(19) United States
(12) Patent Application Publication
(10) Pub. No.: US 2026/0114337 A1
(43) Pub. Date: Apr. 23, 2026

(54) SEMICONDUCTOR DEVICE AND INSULATING SWITCH

(71) Applicant: ROHM CO., LTD., Kyoto (JP)

(72) Inventors: Koji SAITO, Kyoto (JP); Satoru NATE, Kyoto (JP)

(21) Appl. No.: 19/359,854

(22) Filed: Oct. 16, 2025

(30) Foreign Application Priority Data
Oct. 23, 2024 (JP) 2024-186555

(51) Int. Cl. H01L 23/495; H01L 23/00; H01L 23/31; H10D 80/20; H10D 80/30

(52) U.S. Cl. CPC H10W 90/811; H10D 80/211; H10D 80/251; H10D 80/30; H10W 70/417; H10W 70/481; H10W 74/111; H10W 72/884; H10W 90/736; H10W 90/753; H10W 90/756

(57) ABSTRACT

A semiconductor device includes: a switch circuit chip and a control circuit chip, which are mounted on a first die pad; a first conductive bonding material configured to bond the first die pad and the switch circuit chip; and a second conductive bonding material configured to bond the first die pad and the control circuit chip. The switch circuit chip includes: a first semiconductor substrate bonded to the first die pad by the first conductive bonding material; and a first transistor and a second transistor, which have sources connected to each other. Both the first transistor and the second transistor are high electron mobility transistors including nitride semiconductors. The source of the first transistor and the source of the second transistor are electrically connected to the first die pad via the control circuit chip.

### CROSS REFERENCE TO RELATED APPLICATION

The present invention claims priority under 35 U.S.C. § 119 to Japanese Patent Application No. 2024-186555, filed on Oct. 23, 2024, the entire contents of which are incorporated herein by reference.

### TECHNICAL FIELD

The present disclosure relates to a semiconductor device and an insulating switch.

### BACKGROUND

In the related art, there is known a bidirectional switch in which a source of a first MOSFET and a source of a second MOSFET are connected to each other. The bidirectional switch includes a first drain terminal connected to a drain electrode of the first MOSFET, a first gate terminal connected to a gate electrode of the first MOSFET, a second drain terminal connected to a drain electrode of the second MOSFET, a second gate terminal connected to a gate electrode of the second MOSFET, and a common source terminal to which a source electrode of the first MOSFET and a source electrode of the second MOSFET are connected.

### BRIEF DESCRIPTION OF DRAWINGS

The accompanying drawings, which are incorporated in and constitute a part of the specification, illustrate embodiments of the present disclosure.

FIG. 1 is a schematic circuit diagram of an insulating switch including an exemplary semiconductor device according to a first embodiment.

FIG. 2 is a schematic plan view of the semiconductor device shown in FIG. 1.

FIG. 3 is a schematic cross-sectional view of the semiconductor device shown in FIG. 2.

FIG. 4 is a schematic cross-sectional view of an insulating chip in the semiconductor device.

FIG. 5 is a schematic cross-sectional view of the insulating chip in the semiconductor device and shows a portion different from that shown in FIG. 4.

FIG. 6 is a schematic cross-sectional view schematically showing a configuration of a control circuit chip shown in FIG. 3.

FIG. 7 is a partially enlarged schematic plan view showing an internal structure of a switch circuit chip shown in FIG. 3.

FIG. 8 is a schematic cross-sectional view of the switch circuit chip taken along line F8-F8 in FIG. 7.

FIG. 9 is a partially enlarged schematic cross-sectional view showing a control circuit chip, a switch circuit chip, and surroundings thereof in the semiconductor device shown in FIG. 3.

FIG. 10 is a schematic plan view of an exemplary semiconductor device according to a second embodiment.

FIG. 11 is a schematic cross-sectional view schematically showing a configuration of a control circuit chip shown in FIG. 10.

FIG. 12 is a schematic circuit diagram of an insulating switch including an exemplary semiconductor device according to a third embodiment.

FIG. 13 is a schematic plan view of the semiconductor device shown in FIG. 12.

FIG. 14 is a schematic cross-sectional view of a drive circuit chip in a semiconductor device of a modification.

FIG. 15 is a schematic cross-sectional view of an insulating chip in the semiconductor device of the modification.

FIG. 16 is a schematic plan view of the semiconductor device of the modification.

### DETAILED DESCRIPTION

Hereinafter, several embodiments of a semiconductor device of the present disclosure will be described with reference to the accompanying drawings. For the sake of simplicity and clarity of description, components shown in the drawings are not necessarily drawn on a constant scale. In addition, for ease of understanding, hatching lines may be omitted in cross-sectional views. The accompanying drawings are merely illustrative of embodiments of the present disclosure and should not be considered as limiting the present disclosure.

The following detailed description includes devices, systems, and methods embodying exemplary embodiments of the present disclosure. The detailed description is merely explanatory in nature and is not intended to limit the embodiments of the present disclosure or application and uses of such embodiments.

The terms “first,” “second,” “third,” and the like used in the present disclosure are merely used to label and are not necessarily intended to assign any order to their objects. The term “at least one” used in the present disclosure means “one or more” of the desired options. As an example, the term “at least one” used in the present disclosure means “only one option” or “both of two options” if the number of options is two. As another example, the term “at least one” used in the present disclosure means “only one option” or “any combination of two or more options” if the number of options is three or more.

### First Embodiment

### Schematic Configuration of Insulating Switch

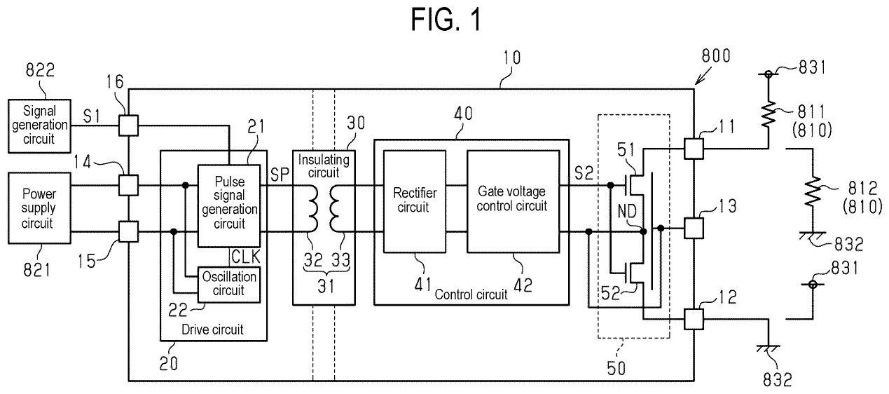

A schematic configuration of an insulating switch 800 including a semiconductor device 10 according to a first embodiment will be described with reference to FIG. 1. FIG. 1 shows the schematic configuration of the insulating switch 800.

The insulating switch 800 shown in FIG. 1 may be mounted on a device such as a sequencer. The insulating switch 800 may be used as a switch for switching on and off a circuit that supplies a driving voltage VD2 to a load 810. In one example, the insulating switch 800 includes a power supply circuit 821 and a signal generation circuit 822, which are electrically connected to a semiconductor device 10. The power supply circuit 821 is configured to supply an operating voltage VD1 to the semiconductor device 10. The operating voltage VD1 is, for example, a direct current voltage. The signal generation circuit 822 is configured to output a control signal S1 for controlling the load 810 to the semiconductor device 10.

The configuration of the insulating switch 800 is not limited to the example shown in FIG. 1 and may be changed arbitrarily. In one example, at least one of the power supply circuit 821 or the signal generation circuit 822 may be provided outside the insulating switch 800. In this case, between the power supply circuit 821 and the signal generation circuit 822, a circuit provided outside the insulating switch 800 is electrically connected to the insulating switch 800.

The semiconductor device 10 is configured to switch, in response to the control signal S1, between a state (on state) in which a current flows through the load 810 and a state (off state) in which no current flows through the load 810. The semiconductor device 10 includes first to sixth terminals 11 to 16.

The first terminal 11 and the second terminal 12 are terminals configured to be electrically connectable to the load 810. That is, the load 810 is connected to the first terminal 11 or the second terminal 12 according to a usage mode of the load 810. In FIG. 1, a first load 811 and a second load 812 are shown as the load 810.

The semiconductor device 10 includes a switch circuit 50 connected between the first terminal 11 and the second terminal 12. The first load 811 indicates a load connected to the insulating switch 800 to be driven in a sink mode as an example of a usage form. The first load 811 is electrically connected between the first terminal 11 and a high potential terminal 831 that supplies the driving voltage VD2 to the first load 811. The second terminal 12 is connected to a low potential terminal 832 that has a lower potential than the driving voltage VD2. The low potential terminal 832 may be a reference terminal that serves as a reference potential for the driving voltage VD2. The high potential terminal 831 and the low potential terminal 832 may be terminals or cables of a power source that supplies electric power for operating the first load 811. The low potential terminal 832 may be, for example, a ground terminal. The driving voltage VD2 is, for example, 36 V. A reference voltage is, for example, 0 V. Each of the driving voltage VD2 and the reference voltage may be changed as appropriate. When the switch circuit 50 is in an on state, a current flows from the first terminal 11 to the second terminal 12.

The second load 812 indicates a load connected to the insulating switch 800 to be driven in a source mode, as an example of another usage form. The second load 812 is connected between the first terminal 11 and the low potential terminal 832. The second terminal 12 is connected to the high potential terminal 831 that supplies the driving voltage VD2. When the switch circuit 50 is in an on state, a current flows from the second terminal 12 to the first terminal 11.

The third terminal 13 is, for example, in an electrically floating state. The fourth terminal 14 and the fifth terminal 15 are terminals configured to be electrically connectable to the power supply circuit 821. The sixth terminal 16 is a terminal configured to be electrically connectable to the signal generation circuit 822.

The semiconductor device 10 includes a drive circuit 20, an insulating circuit 30, a control circuit 40, and the above-mentioned switch circuit 50. The drive circuit 20 is electrically connected to the fourth to sixth terminals 14 to 16. That is, the drive circuit 20 is electrically connectable to the power supply circuit 821 and the signal generation circuit 822. The drive circuit 20 is electrically connected to the insulating circuit 30. The drive circuit 20 is configured to generate a pulse signal SP for controlling the switch circuit 50. The drive circuit 20 is configured to output the pulse signal SP to the insulating circuit 30.

The drive circuit 20 may include, for example, a pulse signal generation circuit 21 and an oscillation circuit 22. The pulse signal generation circuit 21 is electrically connected to both the power supply circuit 821 and the signal generation circuit 822. The oscillation circuit 22 is electrically connected to both the power supply circuit 821 and the pulse signal generation circuit 21.

The oscillation circuit 22 is configured to output a clock signal CLK. The clock signal CLK may be, for example, a square wave. The clock signal CLK has a predetermined frequency and a predetermined duty. The oscillation circuit 22 may be configured to change the frequency of the clock signal CLK. The oscillation circuit 22 may also be configured to output and stop the clock signal CLK by, for example, an enable signal. The pulse signal generation circuit 21 is configured to generate the pulse signal SP based on the clock signal CLK and the control signal S1, and to output the pulse signal SP to the insulating circuit 30. The clock signal CLK may be supplied from outside of the insulating switch 800.

The insulating circuit 30 is electrically connected to the drive circuit 20 and the control circuit 40. The insulating circuit 30 includes a transformer 31. The transformer 31 includes a first coil 32 and a second coil 33. The first coil 32 is electrically connected to the pulse signal generation circuit 21 of the drive circuit 20. Therefore, it can be said that the drive circuit 20 is configured to output a pulse signal to the first coil 32. The second coil 33 is electrically connected to the control circuit 40. The transformer 31 is configured to cause an induced current to flow through the second coil 33 by the pulse signal SP supplied from the pulse signal generation circuit 21 to the first coil 32. Here, the first coil 32 is an example of a “first insulating element,” and the second coil 33 is an example of a “second insulating element.”

The control circuit 40 is electrically connected to the switch circuit 50. The control circuit 40 is configured to control driving the switch circuit 50. The control circuit 40 includes a rectifier circuit 41 and a gate voltage control circuit 42.

The rectifier circuit 41 is configured to rectify the induced current flowing through the second coil 33 of the transformer 31. The rectifier circuit 41 may include, for example, a plurality of diodes that rectify the induced current. Each of the plurality of diodes may be formed by, for example, a diode-connected transistor.

The gate voltage control circuit 42 is electrically connected to the switch circuit 50. The gate voltage control circuit 42 is configured to generate a drive signal S2 for controlling the switch circuit 50 based on a current from the rectifier circuit 41, and to output the drive signal S2 to the switch circuit 50. In one example, the gate voltage control circuit 42 may include circuit elements such as a transistor, a capacitor, and a resistor.

The switch circuit 50 is electrically connected to each of the first to third terminals 11 to 13. The switch circuit 50 may be formed by a bidirectional switch. In one example, the switch circuit 50 has a configuration in which a first transistor 51 and a second transistor 52 are connected in series. The transistors 51 and 52 are high electron mobility transistors (HEMTs) including nitride semiconductors. In one example, each of the first transistor 51 and the second transistor 52 is formed by a normally-off GaN HEMT.

Each of the first transistor 51 and the second transistor 52 includes a source, a drain, and a gate. The gates of the transistors 51 and 52 are electrically connected to the gate voltage control circuit 42. The sources of the transistors 51 and 52 are electrically connected to each other. The sources of the transistors 51 and 52 are electrically connected to the gate voltage control circuit 42. That is, the gate voltage control circuit 42 is electrically connected to each of the gates of the transistors 51 and 52 and each of the sources of the transistors 51 and 52. The drain of the first transistor 51 is electrically connected to the first terminal 11. The drain of the second transistor 52 is electrically connected to the second terminal 12. Therefore, the first transistor 51 and the second transistor 52 are connected in series between the first terminal 11 and the second terminal 12.

The first transistor 51 and the second transistor 52, which are formed by GaN HEMTs, include a substrate. The substrate of the first transistor 51 and the second transistor 52 may be, for example, a silicon (Si) substrate. The substrate of the first transistor 51 and the second transistor 52 may be an integrated single substrate. The substrate may be applied with a source potential of the first transistor 51 and the second transistor 52. In one example, the substrate is electrically connected to the sources of the first transistor 51 and the second transistor 52.

In the insulating switch 800 having the above-mentioned configuration, the pulse signal SP, which is generated by the pulse signal generation circuit 21 based on the control signal S1 from the signal generation circuit 822 and the clock signal CLK from the oscillation circuit 22, is supplied to the first coil 32 of the insulating circuit 30. Thus, an induced current corresponding to the pulse signal SP is generated in the second coil 33 of the insulating circuit 30. The rectifier circuit 41 rectifies the induced current flowing through the second coil 33 to generate a DC voltage. The gate voltage control circuit 42 generates the drive signal S2 by the DC voltage of the rectifier circuit 41. In one example, the rectifier circuit 41 rectifies the induced current from the second coil 33 to generate a desired DC voltage. The DC voltage is, for example, 6 V or more and 7 V or less. The gate voltage control circuit 42 generates the drive signal S2, which has a voltage corresponding to the control of the first transistor 51 and the second transistor 52 of the switch circuit 50, using the DC voltage from the rectifier circuit 41. The voltage of the drive signal S2 may be 5 V or more and 5.5 V or less, for example, 5.25 V. The drive signal S2 is supplied to the gates of the first transistor 51 and the second transistor 52 of the switch circuit 50. Therefore, when the drive signal S2 becomes higher than a threshold voltage of the first transistor 51 and the second transistor 52, the first transistor 51 and the second transistor 52 are turned on. As a result, the switch circuit 50 is electrically conducted. By the electrically conducted switch circuit 50, a current flows from the load 810 (load 811) to the low potential terminal 832 via the switch circuit 50, and the load 810 (load 811) is driven.

When the DC voltage obtained by rectifying the induced current from the second coil 33 by the rectifier circuit 41 is less than a gate threshold value, the gate voltage control circuit 42 may include a step-up circuit that steps the DC voltage up. In other words, the gate voltage control circuit 42 may be configured to step up the DC voltage from the rectifier circuit 41 to generate the drive signal S2 of a voltage required to turn the first transistor 51 and the second transistor 52 on.

### Overall Configuration of Semiconductor Device

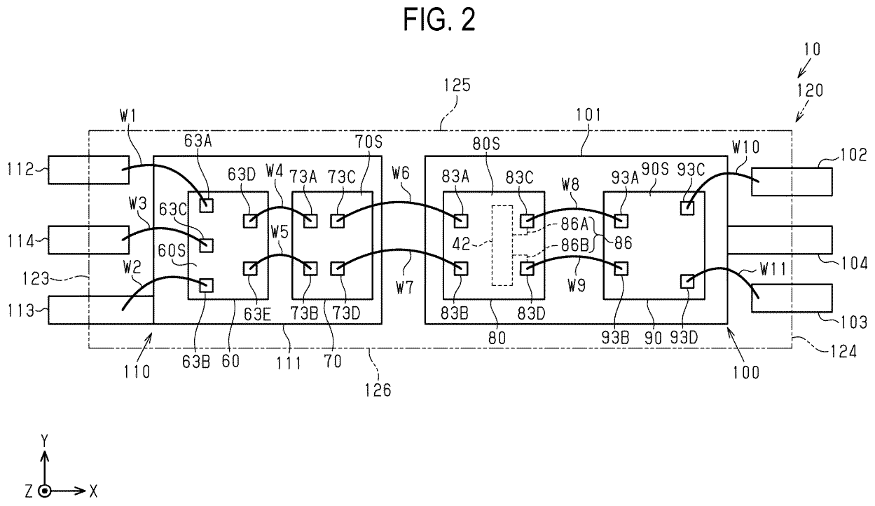

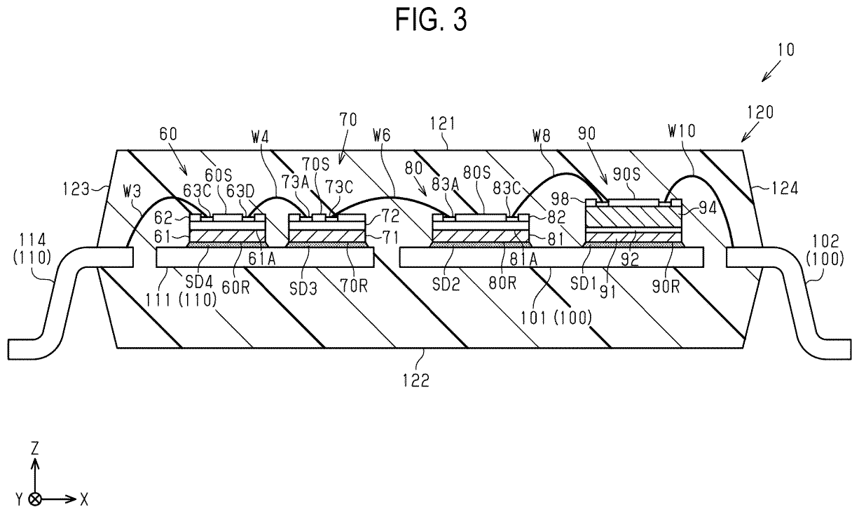

An overall configuration of the semiconductor device 10 of the first embodiment will be described with reference to FIG. 2 and FIG. 3. FIG. 2 shows a schematic internal plan-view structure of the semiconductor device 10. FIG. 3 shows a schematic cross-sectional structure of the semiconductor device 10 taken along an XZ plane. In FIG. 2, a sealing resin 120, which will be described later, is indicated by a two-dot chain line for the convenience of explaining the internal structure of the semiconductor device 10.

In the present disclosure, components may be described based on mutually orthogonal X, Y, and Z axes indicated in the drawings. Here, a direction along the X axis is referred to as an “X direction,” a direction along the Y axis is referred to as a “Y direction,” and a direction along the Z axis is referred to as a “Z direction.” In addition, the term “plan view” used in the present disclosure refers to viewing the semiconductor device 10 in the Z direction.

As shown in FIG. 2 and FIG. 3, the semiconductor device 10 is a semiconductor device in which a plurality of semiconductor chips are packaged together. In the first embodiment, the semiconductor device 10 includes, as the semiconductor chips, a drive circuit chip 60, an insulating chip 70, a control circuit chip 80, and a switch circuit chip 90.

A package format of the semiconductor device 10 is a small outline (SO) type, and is, for example, a small outline package (SOP). The package format of the semiconductor device 10 may be changed arbitrarily. The package format is not limited to the SOP, and may be a quad for non-lead package (QFN), a dual flat package (DFP), a dual inline package (DIP), a quad flat package (QFP), a single inline package (SIP), a small outline J-leaded package (SOJ), or various package structures similar to these packages.

In the first embodiment, the semiconductor device 10 includes a first support 100, a second support 110, and the sealing resin 120. The drive circuit chip 60 is mounted on the second support 110. In one example, the insulating chip 70 is mounted on the second support 110. The control circuit chip 80 is mounted on the first support 100. The switch circuit chip 90 is mounted on the first support 100.

The sealing resin 120 is formed of a resin material having electrical insulating properties. The resin material may be, for example, a resin containing an epoxy resin. The resin material may be colored black or the like. The sealing resin 120 may be in the form of a flat plate with a thickness direction thereof being the Z direction. As shown in FIG. 3, the sealing resin 120 includes a sealing upper surface 121 and a sealing lower surface 122 opposite the sealing upper surface 121. The sealing upper surface 121 and the sealing lower surface 122 are provided at positions spaced apart from each other in the Z direction. The sealing resin 120 includes four sealing side surfaces 123 to 126 (see FIG. 2) that connect the sealing upper surface 121 and the sealing lower surface 122. The sealing side surfaces 123 and 124 constitute both end surfaces of the sealing resin 120 in the X direction. The sealing side surfaces 125 and 126 constitute both end surfaces of the sealing resin 120 in the Y direction.

Each of the first support 100 and the second support 110 has electrical conductivity. The supports 100 and 110 are formed of a material including Cu (copper), Fe (iron), Al (aluminum), and the like. The first support 100 and the second support 110 are provided over both an inside and an outside of the sealing resin 120. The first support 100 and the second support 110 are disposed to be spaced apart from each other in the X direction. The first support 100 is disposed closer to the sealing side surface 124 than the second support 110.

As shown in FIG. 2, the first support 100 includes a first die pad 101 disposed inside the sealing resin 120, and a plurality of first to third terminals 102 to 104 disposed across the inside and outside of the sealing resin 120. The first terminal 102 constitutes the first terminal 11 shown in FIG. 1, the second terminal 103 constitutes the second terminal 12 shown in FIG. 1, and the third terminal 104 constitutes the third terminal 13 shown in FIG. 1.

Both the control circuit chip 80 and the switch circuit chip 90 are mounted on the first die pad 101. In one example, the first die pad 101 is not exposed from the sealing resin 120. The first die pad 101 has a flat plate shape with a thickness direction thereof being the Z direction. In one example, the first die pad 101 has a rectangular shape in a plan view with long sides thereof extending in the X direction and short sides thereof extending in the Y direction.

The first to third terminals 102 to 104 are disposed on an opposite side of the second support 110 in the X direction with respect to the first die pad 101. The first to third terminals 102 to 104 are disposed to be spaced apart from one another in the Y direction. The third terminal 104 is disposed on a side where the first terminal 102 and the second terminal 103 are disposed with respect to the first die pad 101. The third terminal 104 is disposed between the first terminal 102 and the second terminal 103 in the Y direction. Portions of the first to third terminals 102 to 104 protrude from the sealing side surface 124 toward the outside of the sealing resin 120. Each of the first terminal 102 and the second terminal 103 is disposed to be spaced apart from the first die pad 101. The third terminal 104 is integrated with the first die pad 101.

The second support 110 includes a second die pad 111 disposed inside the sealing resin 120, and a plurality of fourth to sixth terminals 112 to 114 disposed across the inside and outside of the sealing resin 120. The fourth terminal 112 constitutes the fourth terminal 14 shown in FIG. 1, the fifth terminal 113 constitutes the fifth terminal 15 shown in FIG. 1, and the sixth terminal 114 constitutes the sixth terminal 16 shown in FIG. 1.

The second die pad 111 is disposed to be spaced apart from the first die pad 101 in the X direction. Both the drive circuit chip 60 and the insulating chip 70 are mounted on the second die pad 111. In one example, the second die pad 111 is not exposed from the sealing resin 120. The second die pad 111 has a flat plate shape with a thickness direction thereof being the Z direction. In one example, the second die pad 111 has a rectangular shape in a plan view with long sides thereof extending in the X direction and short sides thereof extending in the Y direction.

The fourth to sixth terminals 112 to 114 are disposed on an opposite side of the first support 100 in the X direction with respect to the second die pad 111. The fourth to sixth terminals 112 to 114 are disposed to be spaced apart from one another in the Y direction. Portions of the fourth to sixth terminals 112 to 114 protrude from the sealing side surface 123 toward the outside of the sealing resin 120. Each of the fourth terminal 112 and the sixth terminal 114 is disposed to be spaced apart from the second die pad 111. The fifth terminal 113 is integrated with the second die pad 111. The fifth terminal 113 is disposed closer to the sealing side surface 126 than the fourth terminal 112 and the sixth terminal 114. The sixth terminal 114 is disposed between the fourth terminal 112 and the fifth terminal 113 in the Y direction.

As shown in FIG. 2 and FIG. 3, the drive circuit chip 60, the insulating chip 70, the control circuit chip 80, and the switch circuit chip 90 are disposed to be spaced apart from one another in the X direction. Both the insulating chip 70 and the control circuit chip 80 are disposed between the drive circuit chip 60 and the switch circuit chip 90 in the X direction. The insulating chip 70 is disposed between the drive circuit chip 60 and the control circuit chip 80 in the X direction.

The drive circuit chip 60 includes the drive circuit 20 shown in FIG. 1. More specifically, the drive circuit chip 60 includes the pulse signal generation circuit 21 and the oscillation circuit 22 shown in FIG. 1. The drive circuit chip 60 has a flat plate shape with a thickness direction thereof being the Z direction. The drive circuit chip 60 has a rectangular shape having short and long sides in a plan view. The drive circuit chip 60 is mounted on the second die pad 111 with the long sides thereof extending along the Y direction and the short sides thereof extending along the X direction, for example.

As shown in FIG. 3, the drive circuit chip 60 is bonded to the second die pad 111 by a fourth conductive bonding material SD4. The drive circuit chip 60 has a fourth chip front surface 60S and a fourth chip rear surface 60R opposite the fourth chip front surface 60S. The fourth chip rear surface 60R is in contact with the fourth conductive bonding material SD4. As the fourth conductive bonding material SD4, for example, at least one of solder paste, silver (Ag) paste, Cu paste, or gold (Au) paste may be used.

The drive circuit chip 60 includes a fourth semiconductor substrate 61 and a fourth insulator 62 provided over the fourth semiconductor substrate 61. The fourth semiconductor substrate 61 includes the fourth chip rear surface 60R. The fourth insulator 62 includes the fourth chip front surface 60S.

The fourth semiconductor substrate 61 has a flat plate shape with a thickness direction thereof being the Z direction. The fourth semiconductor substrate 61 is formed of, for example, a material containing Si. In one example, a Si substrate may be used for the fourth semiconductor substrate 61. Instead of the Si substrate, a silicon carbide (SiC) substrate or a gallium nitride (GaN) substrate may be used for the fourth semiconductor substrate 61. A fourth semiconductor layer 61A epitaxially grown from the fourth semiconductor substrate 61 is provided over the fourth semiconductor substrate 61. The drive circuit 20 (the pulse signal generation circuit 21 and the oscillation circuit 22) is provided in the fourth semiconductor layer 61A. The fourth insulator 62 is provided over the fourth semiconductor layer 61A. In other words, the fourth semiconductor layer 61A is provided between the fourth insulator 62 and the fourth semiconductor substrate 61.

The fourth insulator 62 is provided over an entirety of the fourth semiconductor layer 61A in a plan view, for example. The fourth insulator 62 may include an insulating layer containing at least one of silicon oxide (SiO₂) or silicon nitride (SiN), and a protective layer provided over the insulating layer. The protective layer may be formed of, for example, polyimide (PI).

As shown in FIG. 2, the drive circuit chip 60 includes first to fifth pads 63A to 63E. The first to fifth pads 63A to 63E are provided in the fourth insulator 62 (see FIG. 3). The first to fifth pads 63A to 63E are exposed from the fourth insulator 62 in a plan view. More specifically, the first to fifth pads 63A to 63E are provided over the insulating layer of the fourth insulator 62. The protective layer is provided to partially cover the first to fifth pads 63A to 63E. Therefore, the first to fifth pads 63A to 63E include portions exposed from the protective layer in a plan view. The first pad 63A and the second pad 63B are electrically connected to the oscillation circuit 22. The third to fifth pads 63C to 63E are electrically connected to the pulse signal generation circuit 21. The first to third pads 63A to 63C are provided in the fourth chip front surface 60S and disposed closer to the fourth to sixth terminals 112 to 114 in a plan view. The fourth pad 63D and the fifth pad 63E are provided in the fourth chip front surface 60S and disposed closer to the insulating chip 70 in a plan view.

The insulating chip 70 includes the transformer 31 shown in FIG. 1. The insulating chip 70 has a flat plate shape with a thickness direction thereof being the Z direction. The insulating chip 70 has a rectangular shape having short and long sides in a plan view. The insulating chip 70 is mounted on the second die pad 111 with the long sides thereof extending along the Y direction and the short sides thereof extending along the X direction, for example.

As shown in FIG. 3, the insulating chip 70 is bonded to the second die pad 111 by a third conductive bonding material SD3. The insulating chip 70 includes a third chip front surface 70S and a third chip rear surface 70R opposite the third chip front surface 70S. The third chip rear surface 70R is in contact with the third conductive bonding material SD3. The third conductive bonding material SD3 may be at least one of solder paste, Ag paste, Cu paste, or Au paste.

The insulating chip 70 includes a third semiconductor substrate 71, a third insulator 72 provided over the third semiconductor substrate 71, and first to fourth pads 73A to 73D (see FIG. 2). The third semiconductor substrate 71 includes the third chip rear surface 70R. The third insulator 72 includes the third chip front surface 70S.

The third semiconductor substrate 71 has a flat plate shape with a thickness direction thereof being the Z direction. The third semiconductor substrate 71 is formed of a material containing Si, for example. In one example, a Si substrate may be used for the third semiconductor substrate 71. Instead of the Si substrate, a SiC substrate may be used for the third semiconductor substrate 71.

As shown in FIG. 2, the first to fourth pads 73A to 73D are provided in the third insulator 72 (see FIG. 3). The first to fourth pads 73A to 73D are exposed from the third insulator 72 in a plan view. The first pad 73A and the second pad 73B are electrically connected to the first coil 32 of the transformer 31. The first pad 73A and the second pad 73B are provided in the third chip front surface 70S and disposed closer to the drive circuit chip 60. The third pad 73C and the fourth pad 73D are electrically connected to the second coil 33 of the transformer 31. The third pad 73C and the fourth pad 73D are disposed at a center of the third chip front surface 70S in the X direction.

The control circuit chip 80 includes the control circuit 40 shown in FIG. 1. The control circuit 40 is configured to control driving the switch circuit chip 90. The control circuit chip 80 has a flat plate shape with a thickness direction thereof being the Z direction. The control circuit chip 80 has a rectangular shape having short and long sides in a plan view. The control circuit chip 80 is mounted on the first die pad 101, for example, with the long sides thereof extending in the Y direction and the short sides thereof extending in the X direction.

As shown in FIG. 3, the control circuit chip 80 is bonded to the first die pad 101 by a second conductive bonding material SD2. The control circuit chip 80 has a second chip front surface 80S and a second chip rear surface 80R opposite the second chip front surface 80S. The second chip rear surface 80R is in contact with the second conductive bonding material SD2. The second conductive bonding material SD2 may be at least one of solder paste, Ag paste, Cu paste, or Au paste.

The control circuit chip 80 includes a second semiconductor substrate 81 and a second insulator 82 provided over the second semiconductor substrate 81. The second semiconductor substrate 81 includes the second chip rear surface 80R. The second insulator 82 includes the second chip front surface 80S. The second semiconductor substrate 81 is electrically connected to the first die pad 101 by the second conductive bonding material SD2.

The second semiconductor substrate 81 has a flat plate shape with a thickness direction thereof being the Z direction. The second semiconductor substrate 81 is formed of a material containing Si, for example. In one example, a Si substrate may be used for the second semiconductor substrate 81. Instead of the Si substrate, a SiC substrate may be used for the second semiconductor substrate 81. A second semiconductor layer 81A epitaxially grown from the second semiconductor substrate 81 is provided over the second semiconductor substrate 81. The control circuit 40 (the rectifier circuit 41 and the gate voltage control circuit 42) is provided in the second semiconductor layer 81A. The second insulator 82 is provided over the second semiconductor layer 81A. In other words, the second semiconductor layer 81A is provided between the second insulator 82 and the second semiconductor substrate 81.

The second insulator 82 is provided over an entirety of the second semiconductor layer 81A in a plan view, for example. The second insulator 82 may include an insulating layer containing at least one of SiO₂ or SiN, and a protective layer provided over the insulating layer. The protective layer may be formed of, for example, PI.

As shown in FIG. 2, the control circuit chip 80 includes first to fourth pads 83A to 83D. The first to fourth pads 83A to 83D are provided in the second insulator 82 (see FIG. 3). The first to fourth pads 83A to 83D are exposed from the second insulator 82 in a plan view. The first pad 73A and the second pad 73B are electrically connected to the rectifier circuit 41 of the control circuit 40. The first pad 83A and the second pad 83B are provided in the second chip front surface 80S and disposed closer to the insulating chip 70. The third pad 83C and the fourth pad 83D are electrically connected to the gate voltage control circuit 42 of the control circuit 40. The third pad 83C and the fourth pad 83D are provided in the second chip front surface 80S and disposed closer to the switch circuit chip 90.

The switch circuit chip 90 includes the switch circuit 50 shown in FIG. 1. The switch circuit chip 90 has a flat plate shape with a thickness direction thereof being the Z direction. The switch circuit chip 90 has a rectangular shape having short and long sides in a plan view. The switch circuit chip 90 is mounted on the first die pad 101 with the long sides thereof extending along the Y direction and the short sides thereof extending along the X direction, for example.

As shown in FIG. 3, the switch circuit chip 90 is bonded to the first die pad 101 by a first conductive bonding material SD1. The switch circuit chip 90 has a first chip front surface 90S and a first chip rear surface 90R opposite the first chip front surface 90S. The first chip rear surface 90R is in contact with the first conductive bonding material SD1. The first conductive bonding material SD1 may be at least one of solder paste, Ag paste, Cu paste, or Au paste.

The switch circuit chip 90 includes a first semiconductor substrate 91 corresponding to the substrates of the first transistor 51 and the second transistor 52 described above, a first insulator 98 provided over the first semiconductor substrate 91, and first to fourth pads 93A to 93D. The first semiconductor substrate 91 includes the first chip rear surface 90R. The first insulator 98 includes the first chip front surface 90S. The first semiconductor substrate 91 is electrically connected to the first die pad 101 by the first conductive bonding material SD1.

Therefore, the first semiconductor substrate 91 is electrically connected to the second semiconductor substrate 81 via the first conductive bonding material SD1, the first die pad 101, and the second conductive bonding material SD2.

The first semiconductor substrate 91 has a flat plate shape with a thickness direction thereof being the Z direction. The first semiconductor substrate 91 is formed of a material containing Si, for example. In one example, a Si substrate may be used for the first semiconductor substrate 91. Instead of the Si substrate, a SiC substrate may be used for the first semiconductor substrate 91.

The first to fourth pads 93A to 93D are provided in the first insulator 98. The first to fourth pads 93A to 93D are exposed from the first insulator 98 in a plan view. The first pad 93A is electrically connected to the gates of the first transistor 51 and the second transistor 52 shown in FIG. 1. The second pad 93B is electrically connected to a node ND between the source of the first transistor 51 and the source of the second transistor 52, and to the substrates of the first transistor 51 and the second transistor 52. The first pad 93A and the second pad 93B are provided in the first chip front surface 90S and disposed closer to the control circuit chip 80. The third pad 93C is electrically connected to the drain of the first transistor 51. The fourth pad 93D is electrically connected to the drain of the second transistor 52. The third pad 93C and the fourth pad 93D are provided in the first chip front surface 90S and disposed closer to the first to third terminals 102 to 104. An internal configuration of the switch circuit chip 90 will be described later.

Next, an electrical connection configuration among the drive circuit chip 60, the insulating chip 70, the control circuit chip 80, and the switch circuit chip 90 will be described with reference to FIG. 2. As shown in FIG. 2, the semiconductor device 10 includes first to eleventh wires W1 to W11 as the electrical connection configuration. The first to eleventh wires W1 to W11 are, for example, bonding wires, and are formed of a material including Au, Al, Cu, Ag, and the like. The first to eleventh wires W1 to W11 are sealed by the sealing resin 120.

The first to third wires W1 to W3 connect the first to third pads 63A to 63C of the drive circuit chip 60 to the fourth to sixth terminals 112 to 114, respectively. The first wire W1 connects the first pad 63A and the fourth terminal 112 to each other, the second wire W2 connects the second pad 63B and the fifth terminal 113 to each other, and the third wire W3 connects the third pad 63C and the sixth terminal 114 to each other. Thus, the first pad 63A is electrically connected to the fourth terminal 112, and the second pad 63B is electrically connected to the fifth terminal 113. That is, both the oscillation circuit 22 and the pulse signal generation circuit 21 (see FIG. 1) are electrically connected to the fourth terminal 112 and the fifth terminal 113. In addition, the third pad 63C is electrically connected to the sixth terminal 114. That is, the pulse signal generation circuit 21 is electrically connected to the sixth terminal 114.

The fourth wire W4 and the fifth wire W5 electrically connect the drive circuit chip 60 and the insulating chip 70. More specifically, the fourth wire W4 and the fifth wire W5 connect the fourth pad 63D and the fifth pad 63E of the drive circuit chip 60 to the first pad 73A and the second pad 73B of the insulating chip 70, respectively. The fourth wire W4 connects the fourth pad 63D and the first pad 73A to each other, and the fifth wire W5 connects the fifth pad 63E and the second pad 73B to each other. Thus, the fourth pad 63D and the first pad 73A are electrically connected to each other, and the fifth pad 63E and the second pad 73B are electrically connected to each other. That is, the pulse signal generation circuit 21 and the first coil 32 of the transformer 31 (see FIG. 1) are electrically connected to each other.

The sixth wire W6 and the seventh wire W7 electrically connect the insulating chip 70 and the control circuit chip 80. More specifically, the sixth wire W6 and the seventh wire W7 connect the third pad 73C and the fourth pad 73D of the insulating chip 70 to the first pad 83A and the second pad 83B of the control circuit chip 80, respectively. The sixth wire W6 connects the third pad 73C and the first pad 83A to each other, and the seventh wire W7 connects the fourth pad 73D and the second pad 83B to each other. Thus, the third pad 73C and the first pad 83A are electrically connected to each other, and the fourth pad 73D and the second pad 83B are electrically connected to each other. That is, the second coil 33 of the transformer 31 and the rectifier circuit 41 (see FIG. 1) are electrically connected to each other.

The eighth wire W8 and the ninth wire W9 connect the third pad 83C and the fourth pad 83D of the control circuit chip 80 to the first pad 93A and the second pad 93B of the switch circuit chip 90, respectively. The eighth wire W8 connects the third pad 83C and the first pad 93A to each other, and the ninth wire W9 connects the fourth pad 83D and the second pad 93B to each other. Thus, the third pad 83C and the first pad 93A are electrically connected to each other, and the fourth pad 83D and the second pad 93B are electrically connected to each other. That is, the gate voltage control circuit 42 shown in FIG. 1 is electrically connected to the gates of the first transistor 51 and the second transistor 52. In addition, the gate voltage control circuit 42 is electrically connected to the source of the first transistor 51 and the source of the second transistor 52.

The tenth wire W10 and the eleventh wire W11 connect the third pad 93C and the fourth pad 93D of the switch circuit chip 90 to the first terminal 102 and the second terminal 103, respectively. The tenth wire W10 connects the third pad 93C and the first terminal 102 to each other, and the eleventh wire W11 connects the fourth pad 93D and the second terminal 103 to each other. Thus, the drain of the first transistor 51 is electrically connected to the first terminal 102, and the drain of the second transistor 52 is electrically connected to the second terminal 103.

Here, the first pad 93A of the switch circuit chip 90 corresponds to a “first input pad,” the second pad 93B corresponds to a “second input pad,” the third pad 93C corresponds to a “first power supply pad,” and the fourth pad 93D corresponds to a “second power supply pad.” The third pad 83C of the control circuit chip 80 corresponds to a “first output pad,” and the fourth pad 83D corresponds to a “second output pad.” The tenth wire W10 corresponds to a “first power supply connector,” and the eleventh wire W11 corresponds to a “second power supply connector.” The eighth wire W8 corresponds to a “first connector,” and the ninth wire W9 corresponds to a “second connector.” The sixth wire W6 and the seventh wire W7 correspond to a “relay connector.” The fourth wire W4 and the fifth wire W5 correspond to an “intermediate connector.” The fourth terminal 112 corresponds to a “power supply terminal,” the fifth terminal 113 corresponds to a “ground terminal,” and the sixth terminal 114 corresponds to a “signal terminal.” The first wire W1 corresponds to a “power supply connector,” and the third wire W3 corresponds to a “signal connector.”

### Insulating Chip

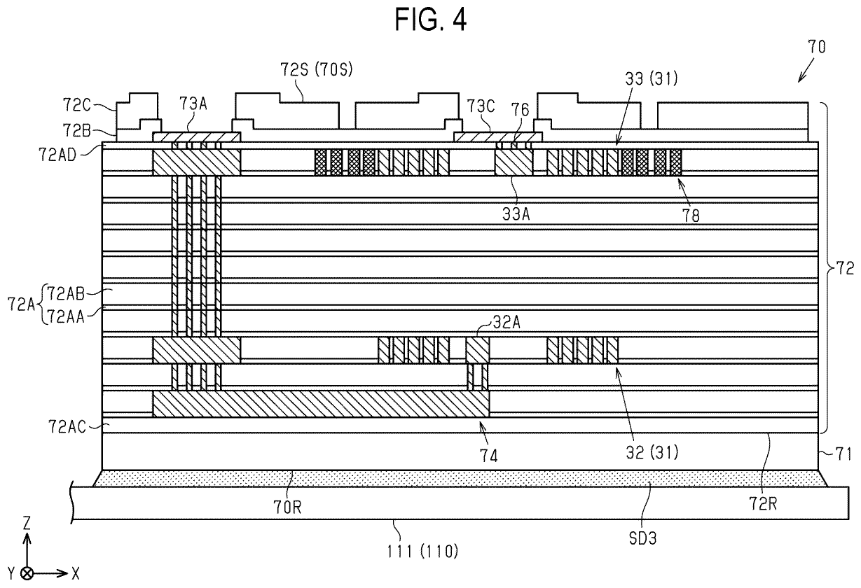

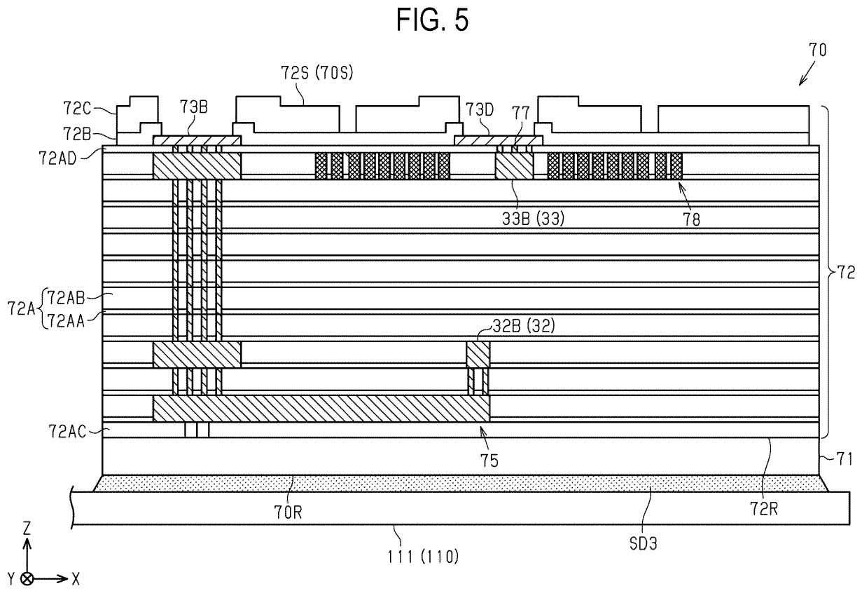

The internal structure of the insulating chip 70 will be described with reference to FIG. 4 and FIG. 5. FIG. 4 shows a schematic cross-sectional structure of the insulating chip 70 taken along the XZ plane passing through the first pad 73A and the third pad 73C in FIG. 2, and FIG. 5 shows a schematic cross-sectional structure of the insulating chip 70 taken along the XZ plane passing through the second pad 73B and the fourth pad 73D in FIG. 2. For the sake of convenience, the fourth to seventh wires W4 to W7 are omitted in FIG. 4 and FIG. 5. Further, in order to ease understanding of the drawings, a thickness of the third insulator 72 is shown to be larger than a thickness of the third semiconductor substrate 71. Actually, the thickness of the third semiconductor substrate 71 is larger than the thickness of the third insulator 72.

As shown in FIG. 4 and FIG. 5, the third insulator 72 provided over the third semiconductor substrate 71 in the insulating chip 70 has an upper surface 72S and a lower surface 72R opposite the upper surface 72S. The lower surface 72R is in contact with the third semiconductor substrate 71.

The third insulator 72 includes a plurality of insulating films 72A stacked in the Z direction from the third semiconductor substrate 71. The insulating films 72A include a first insulating film 72AA and a second insulating film 72AB provided over the first insulating film 72AA. The first insulating film 72AA may be formed of a material including SiN, SiC, nitrogen-added silicon carbide (SiCN), or the like. The second insulating film 72AB is, for example, an interlayer insulating film. The second insulating film 72AB may be formed of a material including SiO₂. A thickness of the second insulating film 72AB may be larger than a thickness of the first insulating film 72AA. Both a lowermost insulating film 72AC in contact with the third semiconductor substrate 71 and an uppermost insulating film 72AD may be formed by the second insulating film 72AB.

As shown in FIG. 4, the first coil 32 and the second coil 33 of the transformer 31 are provided in the plurality of insulating films 72A of the third insulator 72. The first coil 32 and the second coil 33 are disposed to face each other while being spaced apart from each other in the Z direction. The first coil 32 is disposed closer to the lower surface 72R of the third insulator 72 than the second coil 33. It can also be said that the first coil 32 is disposed closer to the third semiconductor substrate 71 than the second coil 33. The plurality of insulating films 72A are interposed between the first coil 32 and the second coil 33 in the Z direction. Both the first coil 32 and the second coil 33 may be formed of a material containing one or more substances appropriately selected from titanium (Ti), titanium nitride (TiN), Au, Ag, Cu, Al, and tungsten (W). In one example, both the first coil 32 and the second coil 33 are formed of a material containing Cu. Both the first coil 32 and the second coil 33 may have, for example, a circular spiral shape in a plan view.

The first coil 32 includes a first inner end 32A that constitutes an inner end in a winding direction of the circular spiral first coil 32, and a first outer end 32B (see FIG. 5) that constitutes an outer end in the winding direction of the first coil 32.

As shown in FIG. 4 and FIG. 5, the insulating chip 70 includes a first inner wiring 74 and a first outer wiring 75. Each of the first inner wiring 74 and the first outer wiring 75 may be formed of a material including one or more substances appropriately selected from Ti, TiN, Au, Ag, Cu, Al, and W.

As shown in FIG. 4, the first inner wiring 74 connects the first inner end 32A of the first coil 32 and the first pad 73A to each other. Thus, the first coil 32 and the first pad 73A are electrically connected to each other. The first inner wiring 74 may include a first inner wiring portion extending in the Z direction to penetrate the plurality of insulating films 72A, and a second inner wiring portion extending in the X direction.

As shown in FIG. 5, the first outer wiring 75 connects the first outer end 32B of the first coil 32 and the second pad 73B to each other. Thus, the first coil 32 and the second pad 73B are electrically connected to each other. The first outer wiring 75 may include a first outer wiring portion extending in the Z direction to penetrate the plurality of insulating films 72A, and a second outer wiring portion extending in the X direction. The first outer wiring 75 may be electrically connected to, for example, the third semiconductor substrate 71.

The second coil 33 includes a second inner end 33A (see FIG. 4) that constitutes an inner end of the circular spiral second coil 33 in a winding direction, and a second outer end 33B that constitutes an outer end of the second coil 33 in the winding direction.

As shown in FIG. 4 and FIG. 5, the insulating chip 70 includes a second inner wiring 76 and a second outer wiring 77. Each of the second inner wiring 76 and the second outer wiring 77 may be formed of a material including one or more substances appropriately selected from Ti, TiN, Au, Ag, Cu, Al, and W.

As shown in FIG. 4, the second inner wiring 76 connects the second inner end 33A of the second coil 33 and the third pad 73C to each other. Thus, the second coil 33 and the third pad 73C are electrically connected to each other. The second inner wiring 76 is disposed at a position overlapping with both the third pad 73C and the second inner end 33A in a plan view. The second inner wiring 76 may be a via that penetrates the uppermost insulating film 72AD in the Z direction.

As shown in FIG. 5, the second outer wiring 77 connects the second outer end 33B of the second coil 33 and the fourth pad 73D to each other. Thus, the second coil 33 and the fourth pad 73D are electrically connected to each other. The second outer wiring 77 is disposed at a position overlapping with both the fourth pad 73D and the second outer end 33B in a plan view. The second outer wiring 77 may be a via that penetrates the uppermost insulating film 72AD in the Z direction.

As shown in FIG. 4 and FIG. 5, the insulating chip 70 includes a dummy coil 78. The dummy coil 78 is provided in the third insulator 72. The dummy coil 78 is provided at the same position as the second coil 33 in the Z direction. The dummy coil 78 is provided to surround the second coil 33 in a plan view. The dummy coil 78 is provided around the second coil 33. The dummy coil 78 may be formed of a material including one or more substances appropriately selected from Ti, TiN, Au, Ag, Cu, Al, and W. The dummy coil 78 can suppress electric field concentration on the second coil 33. The dummy coil 78 may be omitted.

The insulating chip 70 includes a passivation film 72B and a protective film 72C as a third insulator 72. The passivation film 72B is provided over the uppermost insulating film 72AD. The passivation film 72B is a film that protects the insulating film 72A. The passivation film 72B is formed of a material including, for example, SiO₂, SiN, SiCN, and the like.

The first to fourth pads 73A to 73D are provided over the uppermost insulating film 72AD. The passivation film 72B covers each of the first to fourth pads 73A to 73D. Further, the passivation film 72B includes openings that partially expose the first to fourth pads 73A to 73D in the Z direction.

The protective film 72C is provided over the passivation film 72B. The protective film 72C is formed of a material containing PI, for example. The protective film 72C includes openings that communicate with the openings of the passivation film 72B. As a result, the first to fourth pads 73A to 73D are partially exposed in the Z direction from the protective film 72C.

### Control Circuit Chip

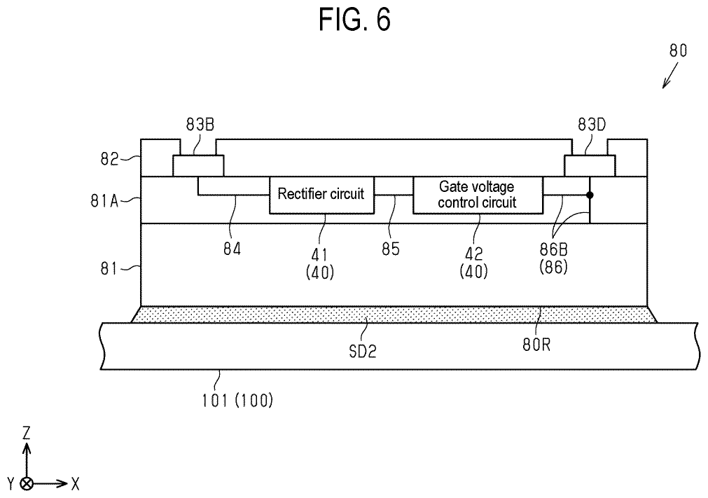

An internal configuration of the control circuit chip 80 will be described with reference to FIG. 6. FIG. 6 shows a schematic cross-sectional structure of the control circuit chip 80 taken along the XZ plane passing through the second pad 83B and the fourth pad 83D in FIG. 2.

As shown in FIG. 6, the control circuit chip 80 includes the second semiconductor layer 81A epitaxially grown from the second semiconductor substrate 81 as described above. Both the rectifier circuit 41 and the gate voltage control circuit 42 are provided, for example, in the second semiconductor layer 81A. The first to fourth pads 83A to 83D (see FIG. 2) are provided over the second semiconductor layer 81A. The second insulator 82 is provided over the second semiconductor layer 81A.

The control circuit chip 80 includes a plurality of first connection wirings 84, a plurality of second connection wirings 85, and a plurality of third connection wirings 86. The first to third connection wirings 84 to 86 are provided in the second semiconductor layer 81A. Each of the first to third connection wirings 84 to 86 may be formed of a material containing one or more substances appropriately selected from Ti, TiN, Au, Ag, Cu, Al, and W.

The first connection wirings 84 connect the rectifier circuit 41 to the first pad 83A and the second pad 83B. The second connection wirings 85 connect the rectifier circuit 41 to the gate voltage control circuit 42. The third connection wirings 86 connect the gate voltage control circuit 42 to the third pad 83C and the fourth pad 83D. As shown in FIG. 2, the third connection wirings 86 include a wiring 86A that connects the gate voltage control circuit 42 and the third pad 83C to each other, and a wiring 86B that connects the gate voltage control circuit 42 to the fourth pad 83D to each other. The wiring 86B is electrically connected to the second semiconductor substrate 81. It can be said that the gate voltage control circuit 42 is configured such that the third pad 83C connected by the wiring 86A has a desired potential difference with respect to the fourth pad 83D connected by the wiring 86B. Further, it can be said that the gate voltage control circuit 42 is configured to generate the drive signal S2 having the potential difference between the third pad 83C and the fourth pad 83D as a drive voltage. The wiring 86B may include a wiring connected to a circuit element constituting the gate voltage control circuit 42, and a region constituting the circuit element, for example, a source region of an n-channel metal-oxide-semiconductor field-effect transistor (MOSFET). Thus, each of the gate voltage control circuit 42 and the fourth pad 83D is electrically connected to the second semiconductor substrate 81. On the other hand, among the plurality of third connection wirings 86, the third connection wiring 86 that connects the gate voltage control circuit 42 and the third pad 83C to each other is not connected to the second semiconductor substrate 81.

### Switch Circuit Chip

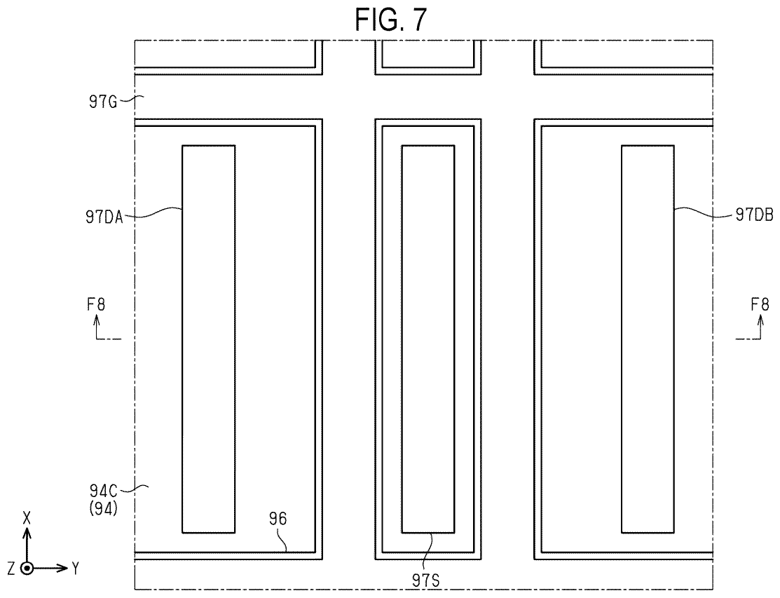

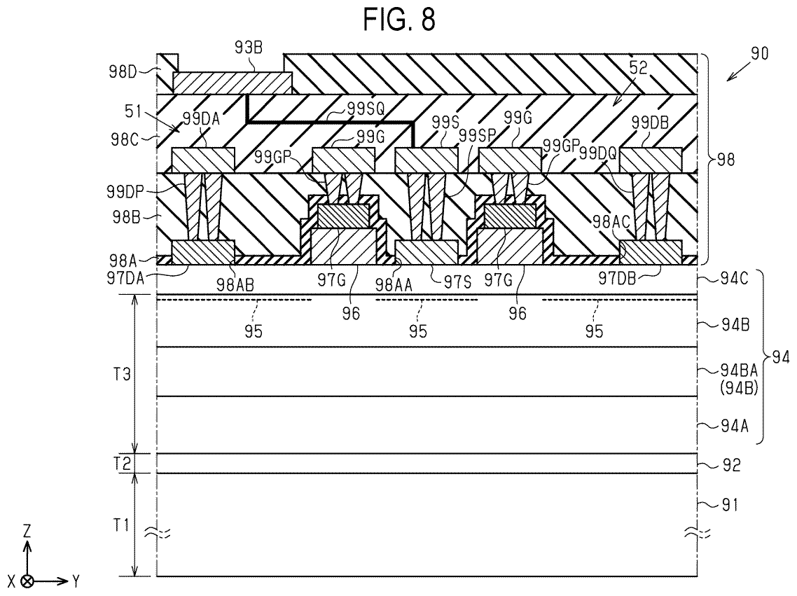

An internal configuration of the switch circuit chip 90 will be described with reference to FIG. 7 and FIG. 8. FIG. 7 shows a partially enlarged schematic plan-view structure of a region in the switch circuit chip 90, in which the first transistor 51 and the second transistor 52 are provided. FIG. 8 shows a schematic cross-sectional structure of the switch circuit chip 90 taken along line F8-F8 in FIG. 7.

As shown in FIG. 8, the switch circuit chip 90 includes an insulating layer 92 provided over the first semiconductor substrate 91 and a nitride semiconductor layer 94 provided over the insulating layer 92. The insulating layer 92 is a layer that insulates the first semiconductor substrate 91 from the nitride semiconductor layer 94. The insulating layer 92 is formed of, for example, aluminum nitride (AlN). In one example, a thickness T2 of the insulating layer 92 may be smaller than a thickness T1 of the first semiconductor substrate 91. In one example, the thickness T2 of the insulating layer 92 may be smaller than a thickness T3 of the nitride semiconductor layer 94. In one example, the thickness T3 of the nitride semiconductor layer 94 may be smaller than the thickness T1 of the first semiconductor substrate 91.

The nitride semiconductor layer 94 includes a buffer layer 94A provided over the insulating layer 92, an electron transit layer 94B provided over the buffer layer 94A, and an electron supply layer 94C provided over the electron transit layer 94B.

The buffer layer 94A may be formed of any material capable of suppressing occurrence of warpage and cracks of a wafer due to mismatching in thermal expansion coefficients between the first semiconductor substrate 91 and the electron transit layer 94B. The buffer layer 94A may include one or more nitride semiconductor layers. The buffer layer 94A may be formed of a material including aluminum gallium nitride (AlGaN). The buffer layer 94A may include, for example, an AlGaN layer and at least one of graded AlGaN layers having different Al compositions. For example, the buffer layer 94A may be formed by a single AlGaN layer, a layer having an AlGaN/GaN superlattice structure, a layer having an AlN/AlGaN superlattice structure, or a layer having an AlN/GaN superlattice structure. The buffer layer 94A may include a plurality of AlGaN layers having different compositions.

In order to suppress a leakage current in the buffer layer 94A, impurities may be introduced into a portion of the buffer layer 94A to make the buffer layer 94A semi-insulating. In this case, the impurities are, for example, carbon (C) or Fe.

The electron transit layer 94B may be, for example, a GaN layer. The electron transit layer 94B may include one or more nitride semiconductor layers. In order to suppress a leakage current in the electron transit layer 94B, the electron transit layer 94B may include a doped layer 94BA, which is made semi-insulating, except for a surface layer region, by introducing acceptor-type impurities into a portion of the electron transit layer 94B. It can be said that the doped layer 94BA is formed by a material including GaN doped with acceptor-type impurities. In this case, the acceptor-type impurities are, for example, C. The doped layer 94BA is provided over the buffer layer 94A. In one example, the doped layer 94BA is provided in the electron transit layer 94B and disposed closer to the buffer layer 94A in the Z direction. In one example, the doped layer 94BA is in contact with the buffer layer 94A.

The electron supply layer 94C is formed by a nitride semiconductor having a larger band gap than the electron transit layer 94B. The electron supply layer 94C may be, for example, an AlGaN layer. Since the band gap increases as an Al composition increases, the electron supply layer 94C, which is an AlGaN layer, has a larger band gap than the electron transit layer 94B, which is a GaN layer. In one example, the electron supply layer 94C is formed of AlₓGa₁₋ₓN with an Al composition ratio x. In this case, the Al composition ratio x is 0.1<x<0.4, and more specifically 0.1<x<0.3. A thickness of the electron supply layer 94C may be smaller than a thickness of the electron transit layer 94B.

The electron transit layer 94B and the electron supply layer 94C have different lattice constants in a bulk region. Therefore, the nitride semiconductor (e.g., GaN) constituting the electron transit layer 94B and the nitride semiconductor (e.g., AlGaN) constituting the electron supply layer 94C form a lattice mismatch type heterojunction. Due to spontaneous polarization of the electron transit layer 94B and the electron supply layer 94C and piezoelectric polarization caused by a compressive stress applied to the heterojunction of the electron transit layer 94B, an energy level of a conduction band of the electron transit layer 94B in a vicinity of an heterojunction interface between the electron transit layer 94B and the electron supply layer 94C becomes lower than the Fermi level. Thus, a two-dimensional electron gas (2DEG) 95 spreads in the electron transit layer 94B in the vicinity of the heterojunction interface between the electron transit layer 94B and the electron supply layer 94C (e.g., at a distance of about several nm from the interface).

The switch circuit chip 90 includes a gate layer 96 provided over a portion of the electron supply layer 94C, and a gate electrode 97G provided over the gate layer 96. Therefore, it can be said that the gate electrode 97G is provided over the electron supply layer 94C. It can also be said that the gate layer 96 is interposed between the gate electrode 97G and the electron supply layer 94C.

The gate layer 96 is formed by a nitride semiconductor. In one example, the gate layer 96 is formed by a nitride semiconductor having a band gap smaller than that of the electron supply layer 94C and containing acceptor-type impurities. In one example, the gate layer 96 is GaN doped with acceptor-type impurities (a p-type GaN layer). The acceptor-type impurities may be at least one of magnesium (Mg), zinc (Zn), or C.

The gate electrode 97G includes one or more metal layers. In one example, the gate electrode 97G may be a TiN layer. In another example, the gate electrode 97G may be formed by a first metal layer formed of Ti, and a second metal layer provided over the first metal layer and formed of TiN. The gate electrode 97G may be formed by a material having a property of forming a Schottky junction with the gate layer 96, for example. One example of such a material is TiN.

The first insulator 98 is provided over the electron supply layer 94C. The first insulator 98 includes a passivation film 98A. The passivation film 98A covers the electron supply layer 94C, the gate layer 96, and the gate electrode 97G. The passivation film 98A may be formed of, for example, one or any combination of SiO₂, SiN, silicon oxynitride (SiON), alumina (Al₂O₃), AlN, and aluminum oxynitride (AlON). The passivation film 98A includes a source opening 98AA, a first drain opening 98AB, and a second drain opening 98AC, each of which exposes a portion of an upper surface of the electron supply layer 94C. The source opening 98AA is disposed between the first drain opening 98AB and the second drain opening 98AC in the Y direction.

The switch circuit chip 90 includes a source electrode 97S provided in the source opening 98AA, a first drain electrode 97DA provided in the first drain opening 98AB, and a second drain electrode 97DB provided in the second drain opening 98AC. The source electrode 97S includes a source contact that is in contact with the electron supply layer 94C via the source opening 98AA. The source contact is in ohmic contact with the 2DEG 95 directly below the electron supply layer 94C. The first drain electrode 97DA includes a first drain contact that is in contact with the electron supply layer 94C via the first drain opening 98AB. The second drain electrode 97DB includes a second drain contact that is in contact with the electron supply layer 94C via the second drain opening 98AC. Both the first drain contact and the second drain contact are in ohmic contact with the 2DEG 95 directly below the electron supply layer 94C. Therefore, it can be said that the source electrode 97S, the first drain electrode 97DA, and the second drain electrode 97DB are provided over the electron supply layer 94C.

The source electrode 97S, the first drain electrode 97DA, and the second drain electrode 97DB include one or more metal layers. In one example, the source electrode 97S, the first drain electrode 97DA, and the second drain electrode 97DB may be formed of one or any combination of Ti, TiN, Al, aluminum silicon copper (AlSiCu), and aluminum copper (AlCu). In one example, the source electrode 97S, the first drain electrode 97DA, and the second drain electrode 97DB are formed by a first metal layer in contact with the electron supply layer 94C, a second metal layer stacked on the first metal layer, a third metal layer stacked on the second metal layer, and a fourth metal layer stacked on the third metal layer. The first metal layer is, for example, a Ti layer, the second metal layer is, for example, an Al layer, the third metal layer is, for example, a Ti layer, and the fourth metal layer is, for example, a TiN layer.

In a structure in which the gate layer 96 is formed by a nitride semiconductor containing acceptor-type impurities, at a zero bias in which no voltage is applied to the gate electrode 97G, the 2DEG 95 in a region directly below the gate layer 96 is depleted, so that a conductive path (channel) is blocked. Thus, a normally-off type HEMT having a gate threshold voltage of a positive value is implemented. When the drive signal S2 of an appropriate voltage (on voltage) is applied to the gate electrode 97G, a channel is formed by the 2DEG 95 in a region of the electron transit layer 94B directly below the gate layer 96, so that the source and the drain are electrically connected.

The first insulator 98 includes a first interlayer insulating film 98B. The first interlayer insulating film 98B is provided to cover the source electrode 97S, the first drain electrode 97DA, and the second drain electrode 97DB. The first interlayer insulating film 98B may be formed of, for example, SiO₂.

The switch circuit chip 90 includes a source wiring 99S, a first drain wiring 99DA, a second drain wiring 99DB, and a gate wiring 99G provided over the first interlayer insulating film 98B. The source wiring 99S, the first drain wiring 99DA, the second drain wiring 99DB, and the gate wiring 99G include one or a plurality of metal layers. The source wiring 99S, the first drain wiring 99DA, the second drain wiring 99DB, and the gate wiring 99G may be formed of one or any combination of Ti, TiN, Al, AlSiCu, and AlCu.

The source wiring 99S is connected to the source electrode 97S by a source via 99SP. Thus, the source wiring 99S is electrically connected to the source electrode 97S. The first drain wiring 99DA is connected to the first drain electrode 97DA by a first drain via 99DP. Thus, the first drain wiring 99DA is electrically connected to the first drain electrode 97DA. The second drain wiring 99DB is connected to the second drain electrode 97DB by a second drain via 99DQ. Thus, the second drain wiring 99DB is electrically connected to the second drain electrode 97DB. The gate wiring 99G is connected to the gate electrode 97G by a gate via 99GP. Thus, the gate wiring 99G is electrically connected to the gate electrode 97G. Each of the source via 99SP, the first drain via 99DP, the second drain via 99DQ, and the gate via 99GP is provided in the first interlayer insulating film 98B. Each of the source via 99SP, the first drain via 99DP, the second drain via 99DQ, and the gate via 99GP may be formed of a material including one or more substances appropriately selected from Ti, TiN, Au, Ag, Cu, Al, and W.

The first insulator 98 includes a second interlayer insulating film 98C. The second interlayer insulating film 98C is provided to cover the source wiring 99S, the first drain wiring 99DA, the second drain wiring 99DB, and the gate wiring 99G. The second interlayer insulating film 98C may be formed of, for example, SiO₂.

The first to fourth pads 93A to 93D (see FIG. 2) are provided over the second interlayer insulating film 98C. The first pad 93A is connected to the gate wiring 99G by a gate connection wiring (not shown). Therefore, the first pad 93A is electrically connected to the gate electrode 97G via the gate connection wiring, the gate wiring 99G, and the gate via 99GP. The second pad 93B is connected to the source wiring 99S by a source connection wiring 99SQ. Therefore, the second pad 93B is electrically connected to the source electrode 97S via the source connection wiring 99SQ, the source wiring 99S, and the source via 99SP. The third pad 93C is connected to the first drain wiring 99DA by a first drain connection wiring (not shown). Therefore, the third pad 93C is electrically connected to the first drain electrode 97DA via the first drain connection wiring, the first drain wiring 99DA, and the first drain via 99DP. The fourth pad 93D is connected to the second drain wiring 99DB by a second drain connection wiring (not shown). Therefore, the fourth pad 93D is electrically connected to the second drain electrode 97DB via the second drain connection wiring, the second drain wiring 99DB, and the second drain via 99DQ.

The first insulator 98 includes a protective film 98D. The protective film 98D is provided to cover the first to fourth pads 93A to 93D. The protective film 98D constitutes the first chip front surface 90S. The protective film 98D is formed of a material including PI, for example.

The protective film 98D includes openings corresponding to the first to fourth pads 93A to 93D, respectively. Thus, the first to fourth pads 93A to 93D are partially exposed from the protective film 98D in the Z direction. As described above, the first transistor 51 and the second transistor 52 are provided between the insulating layer 92 and the first chip front surface 90S in the Z direction.

### Exemplary Plan-View Layout of Switch Circuit Chip

As shown in FIG. 7, the switch circuit chip 90 includes an HEMT structure. For clarity of illustration, FIG. 7 shows a schematic plan-view structure of the source electrode 97S, the gate electrode 97G, the drain electrodes 97DA and 97DB, and surroundings thereof.

The switch circuit chip 90 includes a plurality of transistor elements having HEMT structures. Although FIG. 7 shows, for example, a plurality of transistor elements arranged in the Y direction, actually, the transistor elements are arranged in both the X direction and the Y direction.

The first drain electrode 97DA is provided in each transistor element. The second drain electrode 97DB is provided in each transistor element. The first drain electrode 97DA and the second drain electrode 97DB are disposed to be spaced apart from each other in the Y direction. Each of the drain electrodes 97DA and 97DB has a strip shape extending along the X direction in a plan view.

The source electrode 97S is provided as a common electrode for the transistor element provided with the first drain electrode 97DA and for the transistor element provided with the second drain electrode 97DB. The source electrode 97S is disposed between the first drain electrode 97DA and the second drain electrode 97DB in the Y direction. It can also be said that the first drain electrode 97DA and the second drain electrode 97DB are disposed on both sides of the source electrode 97S in a spaced-apart relationship. The source electrode 97S has a strip shape extending along the X direction in a plan view.

The gate layer 96 and the gate electrode 97G are provided in common to the plurality of transistor elements. The gate layer 96 and the gate electrode 97G are provided in an annular shape to surround the first drain electrode 97DA, the second drain electrode 97DB, and the source electrode 97S individually in a plan view. It can also be said that the gate layer 96 and the gate electrode 97G are provided in a lattice shape in a plan view. Therefore, it can also be said that the gate layer 96 and the gate electrode 97G are disposed between the source electrode 97S and the first drain electrode 97DA, and between the source electrode 97S and the second drain electrode 97DB in a plan view.

Although not shown, each of the source wiring 99S, the first drain wiring 99DA, the second drain wiring 99DB, and the gate wiring 99G may extend in the X direction. The source wiring 99S, the first drain wiring 99DA, the second drain wiring 99DB, and the gate wiring 99G are disposed to be spaced apart from one another in the Y direction.

Each of the first drain wiring 99DA, the second drain wiring 99DB, and the gate wiring 99G may extend in the Y direction. In this case, the source wiring 99S, the first drain wiring 99DA, the second drain wiring 99DB, and the gate wiring 99G are disposed to be spaced apart from each other in the X direction.

### Operation of First Embodiment

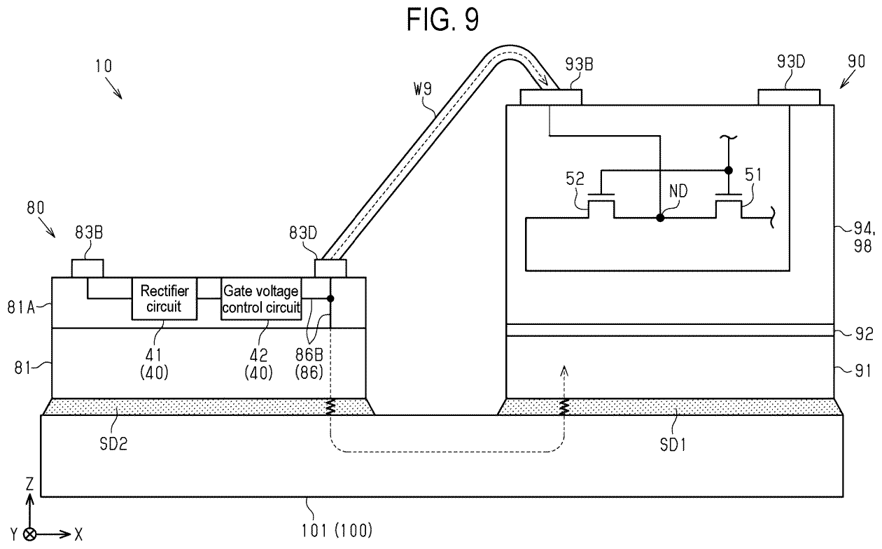

An operation of the semiconductor device 10 according to the first embodiment will be described with reference to FIG. 9. FIG. 9 shows a schematic cross-sectional structure of the control circuit chip 80, the switch circuit chip 90, and surroundings thereof shown in FIG. 3. For the sake of convenience, the second insulator 82, the protective film 98D, the seventh wire W7, and the eleventh wire W11 are omitted in FIG. 9.

As shown in FIG. 9, the source of the first transistor 51 and the source of the second transistor 52 are electrically connected to the second pad 93B of the switch circuit chip 90. The second pad 93B is electrically connected to the fourth pad 83D of the control circuit chip 80 by the ninth wire W9. The fourth pad 83D is electrically connected to the second semiconductor substrate 81 of the control circuit chip 80 by the wiring 86B of the third connection wiring 86. The second semiconductor substrate 81 is electrically connected to the first die pad 101 by the second conductive bonding material SD2. The first semiconductor substrate 91 of the switch circuit chip 90 is electrically connected to the first die pad 101 by the first conductive bonding material SD1. Thus, as indicated by a dot line arrow in FIG. 9, the source of the first transistor 51 and the source of the second transistor 52 are electrically connected to the first die pad 101 via the control circuit chip 80. Further, the source of the first transistor 51 and the source of the second transistor 52 are electrically connected to the first semiconductor substrate 91 via the first die pad 101. Therefore, since a potential of the first semiconductor substrate 91 becomes equal to a potential of the second semiconductor substrate 81, the potential of the first semiconductor substrate 91 is stabilized to a source potential. Furthermore, since the potential of the first semiconductor substrate 91 coincides with the source potential, electrical characteristics of the switch circuit chip 90 is stabilized.

In addition, a pad, which is electrically connected to the source of the first transistor 51 and the source of the second transistor 52 and electrically connected to the first die pad 101 by, for example, a wire, does not need to be provided separately from the second pad 93B. Therefore, the wire described above can also be omitted.

### Effects of First Embodiment

The semiconductor device 10 according to the first embodiment provides the following effects.

(1-1) The semiconductor device 10 includes: the first die pad 101; the switch circuit chip 90 mounted on the first die pad 101; the control circuit chip 80 mounted on the first die pad 101 and including the control circuit 40 configured to control driving the switch circuit chip 90; the first conductive bonding material SD1 configured to bond the first die pad 101 and the switch circuit chip 90; the second conductive bonding material SD2 configured to bond the first die pad 101 and the control circuit chip 80; the first terminal 102 and the second terminal 103, which are disposed to be spaced apart from the first die pad 101; and the sealing resin 120 configured to at least seal the first conductive bonding material SD1, the second conductive bonding material SD2, the switch circuit chip 90, and the control circuit chip 80, and configured to at least partially expose both the first terminal 102 and the second terminal 103. The switch circuit chip 90 includes the first chip front surface 90S, the first chip rear surface 90R opposite the first chip front surface 90S, the first semiconductor substrate 91 constituting the first chip rear surface 90R and bonded to the first die pad 101 by the first conductive bonding material SD1, the insulating layer 92 provided over the first semiconductor substrate 91, and the first transistor 51 and the second transistor 52 that are provided between the insulating layer 92 and the first chip front surface 90S in the thickness direction of the switch circuit chip 90 (Z direction) and have sources connected to each other. Both the first transistor 51 and the second transistor 52 are high electron mobility transistors including a nitride semiconductor. The source of the first transistor 51 and the source of the second transistor 52 are electrically connected to the first die pad 101 via the control circuit chip 80.

With this configuration, the source of the first transistor 51 and the source of the second transistor 52 are electrically connected to the first semiconductor substrate 91 via the control circuit chip 80, the second conductive bonding material SD2, the first die pad 101, and the first conductive bonding material SD1. Therefore, a source potential of each of the transistors 51 and 52 and a potential of the first semiconductor substrate 91 become equal to each other, which stabilizes the potential of the first semiconductor substrate 91. Accordingly, it is possible to stabilize electrical characteristics of the switch circuit chip 90.

(1-2) The control circuit chip 80 includes the second chip front surface 80S, the second chip rear surface 80R opposite the second chip front surface 80S, the second semiconductor substrate 81 constituting the second chip rear surface 80R and bonded to the first die pad 101 by the second conductive bonding material SD2, the third pad 83C exposed from the second chip front surface 80S, and the fourth pad 83D electrically connected to the second semiconductor substrate 81 and exposed from the second chip front surface 80S. The switch circuit chip 90 includes the first pad 93A exposed from the first chip front surface 90S and electrically connected to both the gate of the first transistor 51 and the gate of the second transistor 52, and the second pad 93B exposed from the first chip front surface 90S and electrically connected to the source of the first transistor 51 and the source of the second transistor 52. The semiconductor device 10 further includes the eighth wire W8 connecting the third pad 83C and the first pad 93A, and the ninth wire W9 connecting the fourth pad 83D and the second pad 93B.

With this configuration, the second semiconductor substrate 81 of the control circuit chip 80 is electrically connected to the source of the first transistor 51 and the source of the second transistor 52 via the fourth pad 83D of the control circuit chip 80, the second pad 93B of the switch circuit chip 90, and the ninth wire W9. Therefore, the source potential of each of the transistors 51 and 52 becomes equal to the potential of the second semiconductor substrate 81. Accordingly, it is possible to stabilize the electrical characteristics of the control circuit chip 80 and the switch circuit chip 90.

In addition, by connecting the third pad 83C and the first die pad 101 by the wire, and connecting the second pad 93B and the first die pad 101 by the wire, a configuration of the semiconductor device 10 can be simplified compared to a configuration in which the sources of the respective transistors 51 and 52, the first semiconductor substrate 91, and the second semiconductor substrate 81 are electrically connected.

(1-3) The semiconductor device 10 further includes the third terminal 104 integrated with the first die pad 101. A portion of the third terminal 104 is exposed from the sealing resin 120.

With this configuration, the third terminal 104 serves as a hanging lead for the first die pad 101. Thus, the first die pad 101 can be stably supported when manufacturing the semiconductor device 10.

(1-4) The thickness T2 of the insulating layer 92 is smaller than the thickness T1 of the first semiconductor substrate 91.

With this configuration, the switch circuit chip 90 can be made thinner compared to a case in which the thickness T2 of the insulating layer 92 is equal to or larger than the thickness T1 of the first semiconductor substrate 91.

(1-5) The insulating layer 92 is formed of a material including AlN.

With this configuration, since heat dissipation performance of the insulating layer 92 is improved, it becomes easier to transfer heat from the first transistor 51 and the second transistor 52 to the first semiconductor substrate 91. Accordingly, it is possible to improve heat dissipation performance of the switch circuit chip 90.

(1-6) The semiconductor device 10 further includes the second die pad 111 disposed to be spaced apart from the first die pad 101 in the X direction, the insulating chip 70 mounted on the second die pad 111, and the seventh wire W7 and the eighth wire W8 configured to electrically connect the insulating chip 70 and the control circuit chip 80. The sealing resin 120 seals the insulating chip 70, the seventh wire W7, and the eighth wire W8.

With this configuration, by embedding the insulating chip 70 in the semiconductor device 10, the control circuit chip 80 and the switch circuit chip 90 can be protected when static electricity or the like is applied to the semiconductor device 10. In addition, a length of a path electrically connecting the insulating chip 70 and the control circuit chip 80 can be shortened compared to a case in which the insulating chip 70 is provided outside the semiconductor device 10. Accordingly, it is possible to reduce an inductance caused by a distance of the path described above.

(1-7) The semiconductor device 10 further includes the drive circuit chip 60 mounted on the second die pad 111, and the fourth wire W4 and the fifth wire W5 that connect the insulating chip 70 and the drive circuit chip 60. The sealing resin 120 seals the drive circuit chip 60, the fourth wire W4, and the fifth wire W5.

With this configuration, a length of a path electrically connecting the drive circuit chip 60 and the insulating chip 70 can be made shorter compared to a case in which the drive circuit chip 60 is provided outside the semiconductor device 10. Accordingly, it is possible to reduce an inductance caused by a length of the path described above.

(1-8) The semiconductor device 10 further includes the fourth terminal 112 and the sixth terminal 114 that are disposed to be spaced apart from the second die pad 111, and the fifth terminal 113 integrated with the second die pad 111. The fourth terminal 112, the sixth terminal 114, and the fifth terminal 113 are disposed on the opposite side of the first die pad 101 with respect to the second die pad 111. The sixth terminal 114 is disposed on the side of the first die pad 101 where the fourth terminal 112 and the fifth terminal 113 are disposed.

With this configuration, it is possible to ensure a long creepage distance between the third terminal 104 and the fourth to sixth terminals 112 to 114. Accordingly, it is possible to suppress a decrease in a dielectric strength of the semiconductor device 10.

### Second Embodiment

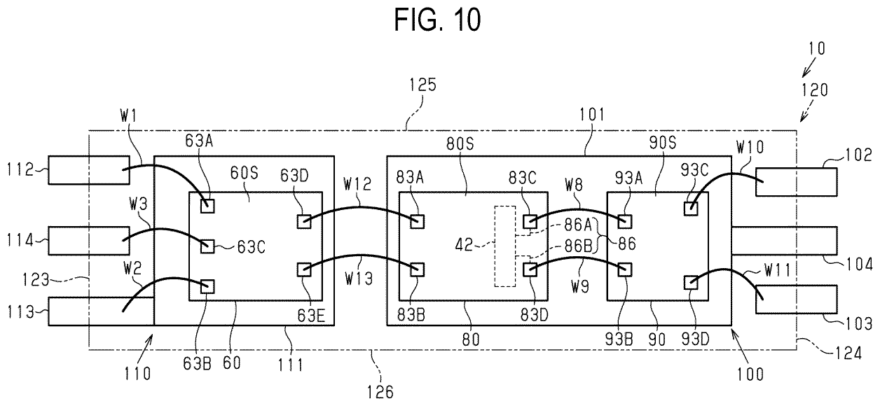

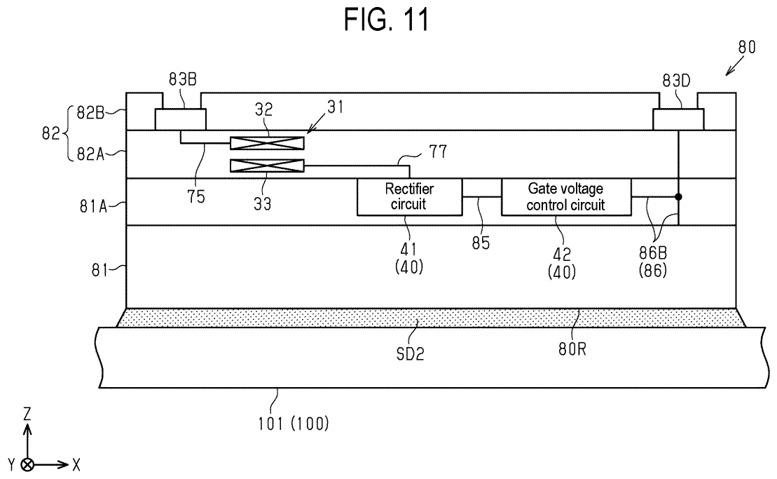

A semiconductor device 10 according to a second embodiment will be described with reference to FIG. 10 and FIG. 11. The semiconductor device 10 according to the second embodiment differs from the semiconductor device 10 according to the first embodiment mainly in omitting the insulating chip 70 and in a configuration of the control circuit chip 80. In the following, components common with the first embodiment are denoted by the same reference numerals, and descriptions thereof will be omitted.

### Overall Configuration of Semiconductor Device

FIG. 10 shows a schematic plan-view structure of the semiconductor device 10 according to the second embodiment. As shown in FIG. 10, the semiconductor device 10 according to the second embodiment includes the drive circuit chip 60, the control circuit chip 80, and the switch circuit chip 90 as semiconductor chips. Configurations of the drive circuit chip 60 and the switch circuit chip 90 are the same as those of the first embodiment.

The drive circuit chip 60 is mounted on the second die pad 111. On the other hand, in the second embodiment, the insulating chip 70 is not mounted. Therefore, the dimension in the X direction of the second die pad 111 may be smaller than the dimension in the X direction of the second die pad 111 in the first embodiment.

The semiconductor device 10 includes a twelfth wire W12 and a thirteenth wire W13 instead of the fourth to seventh wires W4 to W7 of the first embodiment. The twelfth wire W12 and the thirteenth wire W13 connect the drive circuit chip 60 and the control circuit chip 80. The twelfth wire W12 connects the fourth pad 63D of the drive circuit chip 60 and the first pad 83A of the control circuit chip 80 to each other. The thirteenth wire W13 connects the fifth pad 63E of the drive circuit chip 60 and the second pad 83B of the control circuit chip 80 to each other.

The twelfth wire W12 and the thirteenth wire W13 are sealed with the sealing resin 120 (see FIG. 3). The twelfth wire W12 and the thirteenth wire W13 are, for example, bonding wires, and are formed of a material including Au, Al, Cu, Ag, and the like. Here, the twelfth wire W12 and the thirteenth wire W13 are an example of a “chip connector.”

In the second embodiment, an X-direction dimension of the control circuit chip 80 is larger than that of the control circuit chip 80 of the first embodiment. Accordingly, an X-direction dimension of the first die pad 101 on which the control circuit chip 80 is mounted is larger than that of the first die pad 101 of the first embodiment. The X-direction dimension of the first die pad 101 is also larger than an X-direction dimension of the second die pad 111.

### Schematic Configuration of Control Circuit Chip

FIG. 11 schematically shows a cross-sectional structure of the control circuit chip 80 shown in FIG. 10. For the sake of convenience, the ninth wire W9 and the thirteenth wire W13 are omitted in FIG. 11.

As shown in FIG. 11, the control circuit chip 80 includes the transformer 31, the rectifier circuit 41, and the gate voltage control circuit 42. The second insulator 82 of the control circuit chip 80 may include an insulating layer 82A containing at least one of SiO₂ or SiN, and a protective layer 82B provided over the insulating layer 82A. The protective layer 82B may be formed of, for example, PI.

Both the rectifier circuit 41 and the gate voltage control circuit 42 are provided in the second semiconductor layer 81A provided over the second semiconductor substrate 81. The transformer 31 is provided in the insulating layer 82A. The first coil 32 and the second coil 33 of the transformer 31 are disposed to face each other in the Z direction. The second coil 33 is disposed closer to the second semiconductor substrate 81 than the first coil 32. The first inner end 32A (see FIG. 4) of the first coil 32 is connected to the first pad 83A (see FIG. 2) by the first inner wiring 74 (see FIG. 4). The first outer end 32B (see FIG. 5) of the first coil 32 is connected to the second pad 83B by the first outer wiring 75. The second inner end 33A (see FIG. 4) of the second coil 33 is connected to the rectifier circuit 41 by the second inner wiring 76 (see FIG. 4). The second outer end 33B (see FIG. 5) of the second coil 33 is connected to the rectifier circuit 41 by the second outer wiring 77.

The wiring 86A (see FIG. 10) and wiring 86B of the third connection wiring 86 that connect each of the third pad 83C and the fourth pad 83D to the gate voltage control circuit 42 extend to penetrate the insulating layer 82A in the Z direction. The wiring 86B connected to the fourth pad 83D is electrically connected to the second semiconductor substrate 81, as in the first embodiment. Further, the wiring 86A connected to the third pad 83C is not electrically connected to the second semiconductor substrate 81, as in the first embodiment.

### Effects of Second Embodiment

The semiconductor device 10 according to the second embodiment provides the following effects.

(2-1) The semiconductor device 10 includes the second die pad 111 disposed to be spaced apart from the first die pad 101, the drive circuit chip 60 mounted on the second die pad 111, and the twelfth wire W12 and the thirteenth wire W13 that connect the control circuit chip 80 and the drive circuit chip 60. The drive circuit chip 60 includes the drive circuit 20 configured to output a signal to the control circuit chip 80. The control circuit chip 80 includes the rectifier circuit 41, the first coil 32 electrically connected to the drive circuit 20, the second coil 33 disposed to face the first coil 32 and electrically connected to the rectifier circuit 41, and the gate voltage control circuit 42 electrically connected to the rectifier circuit 41. The sealing resin 120 seals the drive circuit chip 60, the twelfth wire W12, and the thirteenth wire W13.

With this configuration, the number of semiconductor chips in the semiconductor device 10 can be reduced. In addition, the number of connectors (wires) connecting the semiconductor chips to one another can be reduced. Accordingly, it is possible to simplify the configuration of the semiconductor device 10. Further, it is possible to reduce the inductance caused by the connectors (wires).

### Third Embodiment

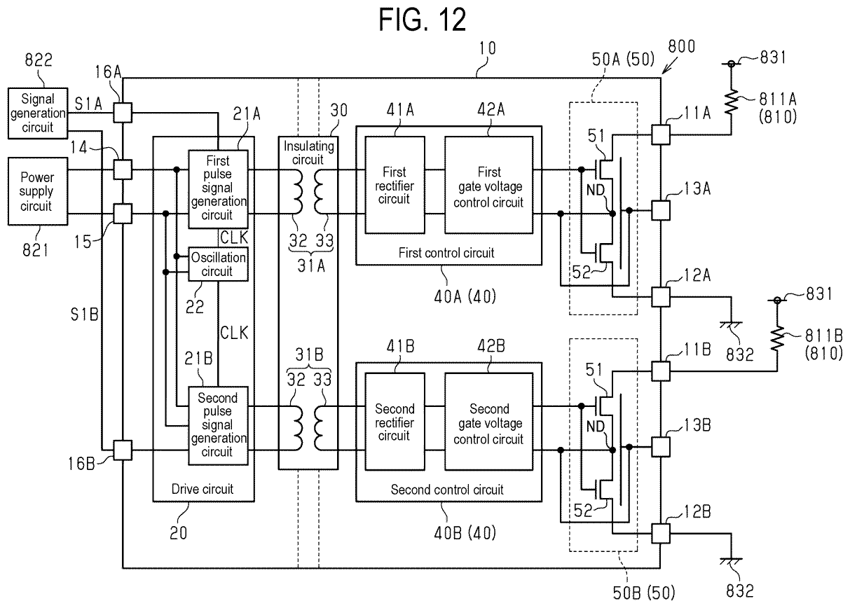

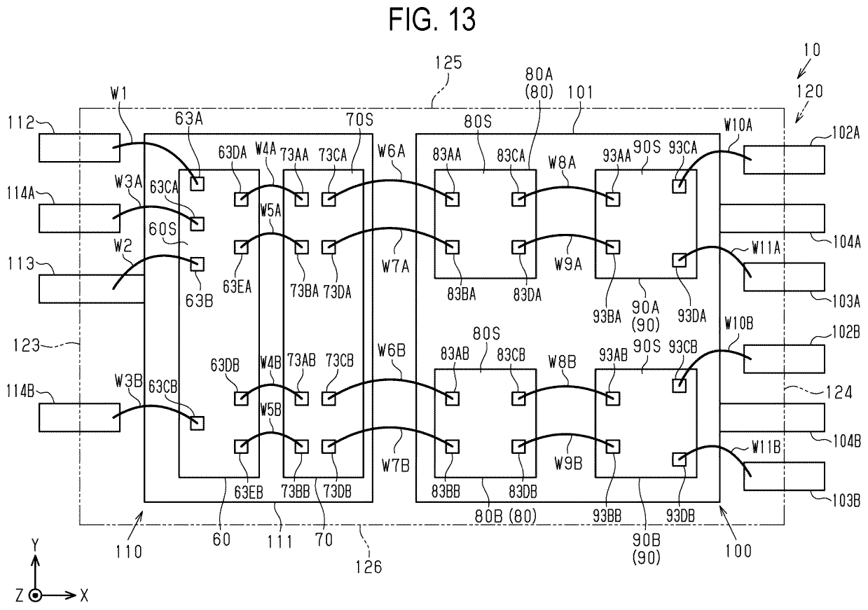

A semiconductor device 10 according to a third embodiment will be described with reference to FIG. 12 and FIG. 13. The semiconductor device 10 according to the third embodiment differs from the semiconductor device 10 according to the first embodiment mainly in that the former includes a plurality of switch circuits 50. In the following, components common with the first embodiment are denoted by the same reference numerals, and descriptions thereof will be omitted.

### Circuit Configuration of Insulating Switch

A circuit configuration of the insulating switch 800 including the semiconductor device 10 of the third embodiment will be described with reference to FIG. 12. FIG. 12 shows a schematic circuit configuration of the insulating switch 800.

As shown in FIG. 12, the plurality of switch circuits 50 of the semiconductor device 10 includes a first switch circuit 50A and a second switch circuit 50B. The control circuit 40 is configured to individually control driving the first switch circuit 50A and the second switch circuit 50B. The semiconductor device 10 includes first to third terminals 11A to 13A corresponding to the first switch circuit 50A, first to third terminals 11B to 13B corresponding to the second switch circuit 50B, the fourth terminal 14, the fifth terminal 15, a sixth terminal 16A corresponding to the first switch circuit 50A, and a sixth terminal 16B corresponding to the second switch circuit 50B.

The drive circuit 20 includes a first pulse signal generation circuit 21A, a second pulse signal generation circuit 21B, and the oscillation circuit 22. The oscillation circuit 22 is electrically connected to each of the first pulse signal generation circuit 21A and the second pulse signal generation circuit 21B. The power supply circuit 821 is electrically connected to the first pulse signal generation circuit 21A, the second pulse signal generation circuit 21B, and the oscillation circuit 22 via the fourth terminal 14 and the fifth terminal 15. The signal generation circuit 822 is electrically connected to the first pulse signal generation circuit 21A and the second pulse signal generation circuit 21B individually. More specifically, the signal generation circuit 822 is electrically connected to the first pulse signal generation circuit 21A via the sixth terminal 16A. The signal generation circuit 822 is electrically connected to the second pulse signal generation circuit 21B via the sixth terminal 16B.

The first pulse signal generation circuit 21A is configured to generate a first pulse signal for controlling driving the first switch circuit 50A, based on a control signal S1A of the signal generation circuit 822 and the clock signal CLK of the oscillation circuit 22. The second pulse signal generation circuit 21B is configured to generate a second pulse signal for controlling driving the second switch circuit 50B, based on a control signal S1B of the signal generation circuit 822 and the clock signal CLK of the oscillation circuit 22.

The insulating circuit 30 includes a first transformer 31A and a second transformer 31B. Configurations of the transformers 31A and 31B are the same as, for example, the transformer 31 of the first embodiment (see FIG. 1). A first coil 32 of the first transformer 31A is electrically connected to the first pulse signal generation circuit 21A. A first coil 32 of the second transformer 31B is electrically connected to the second pulse signal generation circuit 21B.

The control circuit 40 includes a first control circuit 40A electrically connected to the first switch circuit 50A and a second control circuit 40B electrically connected to the second switch circuit 50B.

The first control circuit 40A includes a first rectifier circuit 41A and a first gate voltage control circuit 42A. The first rectifier circuit 41A is electrically connected to a second coil 33 of the first transformer 31A. The first rectifier circuit 41A is configured to rectify an induced current generated in the second coil 33 of the first transformer 31A. The first gate voltage control circuit 42A is electrically connected to the first rectifier circuit 41A. The first gate voltage control circuit 42A is configured to supply a gate voltage to each of a first transistor 51 and a second transistor 52 of a first switch circuit chip 90A.

The second control circuit 40B includes a second rectifier circuit 41B and a second gate voltage control circuit 42B. The second rectifier circuit 41B is configured to rectify an induced current generated in a second coil 33 of the second transformer 31B. The second rectifier circuit 41B is electrically connected to the second coil 33 of the second transformer 31B. The second gate voltage control circuit 42B is electrically connected to the second rectifier circuit 41B. The second gate voltage control circuit 42B is configured to supply a gate voltage to each of a first transistor 51 and a second transistor 52 of a second switch circuit chip 90B.

Both the first switch circuit 50A and the second switch circuit 50B include the first transistor 51 and the second transistor 52. An electrical connection configuration between the first transistor 51 and the second transistor 52 in each of the switch circuits 50A and 50B is the same as that in the first embodiment. The first gate voltage control circuit 42A is electrically connected to each of the gates of the transistors 51 and 52 of the first switch circuit 50A and a node ND between sources of the transistors 51 and 52. The second gate voltage control circuit 42B is electrically connected to each of the gates of the transistors 51 and 52 of the second switch circuit 50B and a node ND between the sources of the transistors 51 and 52.

A drain of the first transistor 51 of the first switch circuit 50A is electrically connected to the first terminal 11A, and a drain of the second transistor 52 is electrically connected to the second terminal 12A. The node ND between the sources of the transistors 51 and 52 of the first switch circuit 50A is electrically connected to the third terminal 13A. A drain of the first transistor 51 of the second switch circuit 50B is electrically connected to the first terminal 11B, and a drain of the second transistor 52 is electrically connected to the second terminal 12B. The node ND between the sources of the transistors 51 of the second switch circuit 50B is electrically connected to the third terminal 13B.

In the example shown in FIG. 12, a first load 811A is electrically connected between the high potential terminal 831 and the first terminal 11A. The second terminal 12A is electrically connected to the low potential terminal 832. A first load 811B is electrically connected between the high potential terminal 831 and the first terminal 11B. The second terminal 12B is electrically connected to the low potential terminal 832. The second load 812 shown in FIG. 1 may be connected to the first terminals 11A and 11B.

### Configuration of Semiconductor Device

A configuration of the semiconductor device 10 according to the third embodiment will be described with reference to FIG. 13. FIG. 13 schematically shows a plan-view structure of the semiconductor device 10 shown in FIG. 12. In the following description, reference is made to FIG. 12 for circuits included in each chip.

As shown in FIG. 13, the semiconductor device 10 includes a plurality of control circuit chips 80 and a plurality of switch circuit chips 90. The plurality of control circuit chips 80 includes a first control circuit chip 80A including the first control circuit 40A, and a second control circuit chip 80B including the second control circuit 40B. The plurality of switch circuit chips 90 includes a first switch circuit chip 90A including the first switch circuit 50A, and a second switch circuit chip 90B including the second switch circuit 50B.

The first support 100 includes a first terminal 102A and a second terminal 103A that correspond to the first switch circuit chip 90A, a first terminal 102B and a second terminal 103B that correspond to the second switch circuit chip 90B, and third terminals 104A and 104B. The first terminals 102A and 102B, the second terminals 103A and 103B, and the third terminals 104A and 104B are disposed on an opposite side of the second support 110 in the X direction with respect to the first die pad 101. The third terminals 104A and 104B are integrated with the first die pad 101. The third terminal 104A is disposed between the first terminal 102A and the second terminal 103A in the Y direction. The third terminal 104B is disposed between the first terminal 102B and the second terminal 103B in the Y direction.

The second support 110 includes a fourth terminal 112, a fifth terminal 113, a sixth terminal 114A corresponding to the first switch circuit chip 90A, and a sixth terminal 114B corresponding to the second switch circuit chip 90B. The fourth terminal 112, the fifth terminal 113, and the sixth terminals 114A and 114B are disposed on an opposite side of the first support 100 in the X direction with respect to the second die pad 111. The fifth terminal 113 is integrated with the second die pad 111.

The drive circuit chip 60 includes a first pad 63A, a second pad 63B, a third pad 63CA corresponding to the sixth terminal 114A, and a third pad 63CB corresponding to the sixth terminal 114B. The semiconductor device 10 includes a third wire W3A that connects the sixth terminal 114A and the third pad 63CA to each other, and a third wire W3B that connects the sixth terminal 114B and the third pad 63CB to each other. The first pad 63A, the second pad 63B, the third pad 63CA, a fourth pad 63DA, and a fifth pad 63EA are provided in the fourth chip front surface 60S and disposed closer to the sealing side surface 125 of the sealing resin 120. The third pad 63CB, the fourth pad 63DB, and the fifth pad 63EB are provided in the fourth chip front surface 60S and disposed closer to the sealing side surface 126 of the sealing resin 120.

The first pad 63A, the second pad 63B, and the third pad 63CA are electrically connected to the first pulse signal generation circuit 21A. The first pad 63A, the second pad 63B, and the third pad 63CB are electrically connected to the second pulse signal generation circuit 21B. The first pad 63A and the second pad 63B are electrically connected to the oscillation circuit 22.

The drive circuit chip 60 includes the fourth pad 63DA and the fifth pad 63EA that are electrically connected to the first pulse signal generation circuit 21A, and the fourth pad 63DB and the fifth pad 63EB that are electrically connected to the second pulse signal generation circuit 21B.

The insulating chip 70 includes the first transformer 31A and the second transformer 31B. The first transformer 31A and the second transformer 31B are arranged side by side in the Y direction in a plan view, for example. The first transformer 31A is provided in the third chip front surface 70S and disposed closer to the sealing side surface 125 of the sealing resin 120.

The second transformer 31B is provided in the third chip front surface 70S and disposed closer to the sealing side surface 126 of the sealing resin 120. A configuration of each of the transformers 31A and 31B may be the same as that of the transformer 31 of the first embodiment, for example.

The insulating chip 70 includes first to fourth pads 73AA to 73DA and 73AB to 73DB. The first to fourth pads 73AA to 73DA are pads corresponding to the first transformer 31A, and the first to fourth pads 73AB to 73DB are pads corresponding to the second transformer 31B. The first to fourth pads 73AA to 73DA are provided in the third chip front surface 70S and disposed closer to the sealing side surface 125 of the sealing resin 120. The first to fourth pads 73AB to 73DB are provided in the third chip front surface 70S and disposed closer to the sealing side surface 126 of the sealing resin 120.

The first pad 73AA and the second pad 73BA are electrically connected to the first coil 32 of the first transformer 31A. The third pad 73CA and the fourth pad 73DA are electrically connected to the second coil 33 of the first transformer 31A. The first pad 73AB and the second pad 73BB are electrically connected to the first coil 32 of the second transformer 31B. The third pad 73CB and the fourth pad 73DB are electrically connected to the second coil 33 of the second transformer 31B.

The semiconductor device 10 includes fourth wires W4A and W4B and fifth wires W5A and W5B. The fourth wire W4A connects the fourth pad 63DA of the drive circuit chip 60 and the first pad 73AA of the insulating chip 70 to each other. The fifth wire W5A connects the fifth pad 63EA of the drive circuit chip 60 and the second pad 73BA of the insulating chip 70 to each other. The fourth wire W4B connects the fourth pad 63DB of the drive circuit chip 60 and the first pad 73AB of the insulating chip 70 to each other. The fifth wire W5B connects the fifth pad 63EB of the drive circuit chip 60 and the second pad 73BB of the insulating chip 70 to each other. Thus, the first pulse signal generation circuit 21A and the first coil 32 of the first transformer 31A are electrically connected to each other, and the second pulse signal generation circuit 21B and the first coil 32 of the second transformer 31B are electrically connected to each other.

Each of the first control circuit chip 80A and the second control circuit chip 80B has the same configuration as that of the control circuit chip 80 of the first embodiment. That is, each of the first control circuit chip 80A and the second control circuit chip 80B includes the second chip front surface 80S, the second chip rear surface 80R, the second semiconductor substrate 81, and the second insulator 82.

Both the first control circuit chip 80A and the second control circuit chip 80B are mounted on the first die pad 101. Both the first control circuit chip 80A and the second control circuit chip 80B are bonded to the first die pad 101 by the second conductive bonding material SD2 (see FIG. 3). The first control circuit chip 80A and the second control circuit chip 80B are disposed at the same position in the X direction and spaced apart from each other in the Y direction.

The first control circuit chip 80A includes first to fourth pads 83AA to 83DA. The first pad 83AA and the second pad 83BA are electrically connected to the first rectifier circuit 41A. The third pad 83CA and the fourth pad 83DA are electrically connected to the first gate voltage control circuit 42A. The fourth pad 83DA is electrically connected to the second semiconductor substrate 81 (not shown) of the first control circuit chip 80A. The third pad 83CA is not electrically connected to the second semiconductor substrate 81 of the first control circuit chip 80A.

The second control circuit chip 80B includes first to fourth pads 83AB to 83DB. The first pad 83AB and the second pad 83BB are electrically connected to the second rectifier circuit 41B. The third pad 83CB and the fourth pad 83DB are electrically connected to the second gate voltage control circuit 42B. The fourth pad 83DB is electrically connected to the second semiconductor substrate 81 (not shown) of the second control circuit chip 80B. The third pad 83CB is not electrically connected to the second semiconductor substrate 81 of the second control circuit chip 80B.

The semiconductor device 10 includes sixth wires W6A and W6B and seventh wires W7A and W7B. The sixth wire W6A connects the third pad 73CA of the insulating chip 70 and the first pad 83AA of the first control circuit chip 80A to each other. The seventh wire W7A connects the fourth pad 73DA of the insulating chip 70 and the second pad 83BA of the first control circuit chip 80A to each other. The sixth wire W6B connects the third pad 73CB of the insulating chip 70 and the first pad 83AB of the second control circuit chip 80B to each other. The seventh wire W7B connects the fourth pad 73DB of the insulating chip 70 and the second pad 83BB of the second control circuit chip 80B to each other.

Each of the first switch circuit chip 90A and the second switch circuit chip 90B has the same configuration as that of the switch circuit chip 90 of the first embodiment. Both the first switch circuit chip 90A and the second switch circuit chip 90B are mounted on the first die pad 101. Both the first switch circuit chip 90A and the second switch circuit chip 90B are bonded to the first die pad 101 by the first conductive bonding material SD1 (see FIG. 3). The first switch circuit chip 90A and the second switch circuit chip 90B are disposed at the same position in the X direction and spaced apart from each other in the Y direction.

The first switch circuit chip 90A includes first to fourth pads 93AA to 93DA. The first pad 93AA is electrically connected to the gate of the first transistor 51 and the gate of the second transistor 52 of the first switch circuit 50A. The second pad 93BA is electrically connected to the node ND between the source of the first transistor 51 and the source of the second transistor 52 of the first switch circuit 50A. The third pad 93CA is electrically connected to the drain of the first transistor 51 of the first switch circuit 50A. The fourth pad 93DA is electrically connected to the drain of the second transistor 52 of the first switch circuit 50A.

The second switch circuit chip 90B includes first to fourth pads 93AB to 93DB. The first pad 93AB is electrically connected to the gate of the first transistor 51 and the gate of the second transistor 52 of the second switch circuit 50B. The second pad 93BB is electrically connected to the node ND between the source of the first transistor 51 and the source of the second transistor 52 of the second switch circuit 50B. The third pad 93CB is electrically connected to the drain of the first transistor 51 of the second switch circuit 50B. The fourth pad 93DB is electrically connected to the drain of the second transistor 52 of the second switch circuit 50B.

The semiconductor device 10 includes eighth to eleventh wires W8A to W11A and W8B to W11B. The eighth wire W8A connects the third pad 83CA of the first control circuit chip 80A and the first pad 93AA of the first switch circuit chip 90A to each other. The ninth wire W9A connects the fourth pad 83DA of the first control circuit chip 80A and the second pad 93BA of the first switch circuit chip 90A to each other. The tenth wire W10A connects the third pad 93CA of the first switch circuit chip 90A and the first terminal 102A to each other. The eleventh wire W11A connects the fourth pad 93DA of the first switch circuit chip 90A and the second terminal 103A to each other. The eighth wire W8B connects the third pad 83CB of the second control circuit chip 80B and the first pad 93AB of the second switch circuit chip 90B to each other. The ninth wire W9B connects the fourth pad 83DB of the second control circuit chip 80B and the second pad 93BB of the first switch circuit chip 90A to each other. The tenth wire W10B connects the third pad 93CB of the second switch circuit chip 90B and the first terminal 102B to each other. The eleventh wire W11B connects the fourth pad 93DA of the second switch circuit chip 90B and the second terminal 103B to each other.

Here, the first pad 93AA of the first switch circuit chip 90A corresponds to a “first input pad,” and the second pad 93BA corresponds to a “second input pad.” The first pad 93AB of the second switch circuit chip 90B corresponds to a “third input pad,” and the second pad 93BB corresponds to a “fourth input pad.” The third pad 83CA of the first control circuit chip 80A corresponds to a “first output pad,” the fourth pad 83DA corresponds to a “second output pad,” the third pad 83CB of the second control circuit chip 80B corresponds to a “third output pad,” and the fourth pad 83 DB corresponds to a “fourth output pad.” The eighth wire W8A corresponds to a “first connector,” the ninth wire W9A corresponds to a “second connector,” the eighth wire W8B corresponds to a “third connector,” and the ninth wire W9B corresponds to a “fourth connector.” The sixth wires W6A and W6B and the seventh wires W7A and W7B correspond to a “relay connector.” The fourth wires W4A and W4B and the fifth wires W5A and W5B correspond to an “intermediate connector.” The fourth terminal 112 corresponds to a “power supply terminal,” the fifth terminal 113 corresponds to a “ground terminal,” and the sixth terminals 114A and 114B correspond to a “signal terminal.” The first wire W1 corresponds to a “power supply connector,” and the third wires W3A and W3B correspond to a “signal connector.” The third pad 93CA of the first switch circuit chip 90A and the third pad 93CB of the second switch circuit chip 90B correspond to a “first power supply pad.” The fourth pad 93DA of the first switch circuit chip 90A and the fourth pad 93DB of the second switch circuit chip 90B correspond to a “second power supply pad.” The tenth wires W10A and W10B correspond to a “first power supply connector,” and the eleventh wires W11A and W11B correspond to a “second power supply connector.”

### Effects of Third Embodiment

The semiconductor device 10 according to the third embodiment provides the following effects.

(3-1) The semiconductor device 10 includes, as switch circuit chips, the first switch circuit chip 90A and the second switch circuit chip 90B. Each of the first switch circuit chip 90A and the second switch circuit chip 90B includes the first transistor 51 and the second transistor 52 having sources connected in series to each other. Both the first transistor 51 and the second transistor 52 are high electron mobility transistors including nitride semiconductors. The source of the first transistor 51 and the source of the second transistor 52 of each of the first switch circuit chip 90A and the second switch circuit chip 90B are electrically connected to the first die pad 101 via the control circuit chip 80.

With this configuration, the source of the first transistor 51 and the source of the second transistor 52 of the first switch circuit chip 90A are electrically connected to the first semiconductor substrate 91 of the first switch circuit chip 90A via the control circuit chip 80, the second conductive bonding material SD2, the first die pad 101, and the first conductive bonding material SD1. Therefore, the source potential of each of the transistors 51 and 52 and the potential of the first semiconductor substrate 91 of the first switch circuit chip 90A become equal to each other, which stabilizes the potential of the first semiconductor substrate 91 of the first switch circuit chip 90A. Accordingly, it is possible to stabilize electrical characteristics of the first switch circuit chip 90A.

Further, the source of the first transistor 51 and the source of the second transistor 52 of the second switch circuit chip 90B are electrically connected to the first semiconductor substrate 91 of the second switch circuit chip 90B via the control circuit chip 80, the second conductive bonding material SD2, the first die pad 101, and the first conductive bonding material SD1. Therefore, the source potential of each of the transistors 51 and 52 and the potential of the first semiconductor substrate 91 of the second switch circuit chip 90B become equal to each other, which stabilizes the potential of the first semiconductor substrate 91 of the second switch circuit chip 90B. Accordingly, it is possible to stabilize electrical characteristics of the second switch circuit chip 90B.

### Modifications

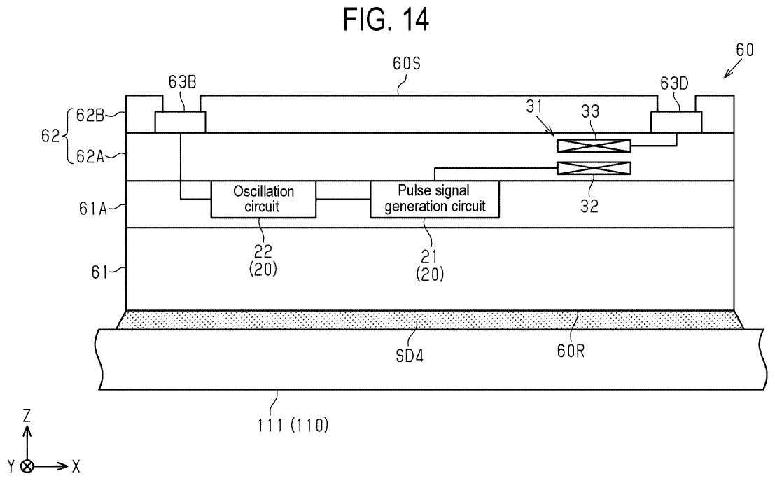

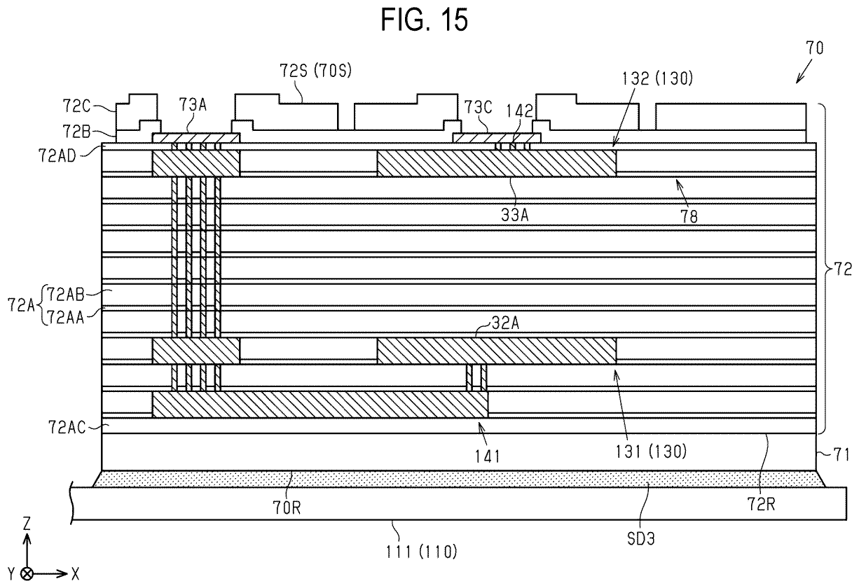

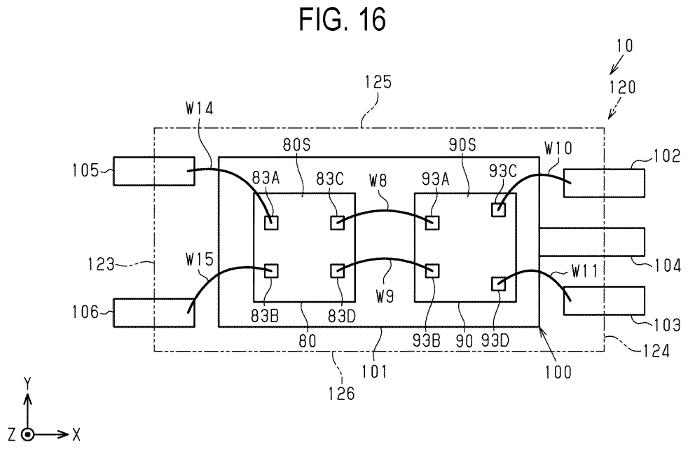

The above-described embodiments may be modified as follows. The above-described embodiments and the following modifications may be implemented in combination to the extent that they are not technically inconsistent.
The third embodiment may be combined with the second embodiment.
In the first and second embodiments, the position of the third terminal 104 of the first support 100 may be changed arbitrarily. In one example, the third terminal 104 may be disposed closer to the sealing side surface 125 of the sealing resin 120 than the first terminal 102 in a plan view. In one example, the third terminal 104 may be disposed closer to the sealing side surface 126 than the second terminal 103 in a plan view. In one example, the third terminal 104 may be exposed from the sealing side surface 125 or the sealing side surface 126 instead of the sealing side surface 124. Further, the arrangement of the first to third terminals 102A to 104A and the arrangement of the first to third terminals 102B to 104B in the first support 100 of the third embodiment may also be changed in a similar manner.
In the first and second embodiments, a plurality of third terminals 104 of the first support 100 may be provided.
In the third embodiment, one of the third terminals 104A and 104B of the first support 100 may be omitted.
In the first and second embodiments, the arrangement of the fourth to sixth terminals 112 to 114 of the second support 110 may be changed arbitrarily. In one example, the fifth terminal 113 may be disposed between the fourth terminal 112 and the sixth terminal 114 in the Y direction.
In the third embodiment, the arrangement of the fourth terminal 112, the fifth terminal 113, and the sixth terminals 114A and 114B of the second support 110 may be changed arbitrarily.
In each embodiment, the thickness T2 of the insulating layer 92 may be changed arbitrarily. In one example, the thickness T2 of the insulating layer 92 may be equal to or larger than the thickness T1 of the first semiconductor substrate 91.
In each embodiment, the material constituting the insulating layer 92 may be changed arbitrarily as long as it is an insulating material.
In each embodiment, the doped layer 94BA may be omitted from the switch circuit chip 90.
In each embodiment, the configurations of the insulating layer 92 and the nitride semiconductor layer 94 may be changed arbitrarily. In one example, the insulating layer 92 and the buffer layer 94A and the doped layer 94BA of the nitride semiconductor layer 94 may serve as an insulating layer that insulates the first semiconductor substrate 91 and the first and second transistors 51 and 52. In this case, the nitride semiconductor layer 94 is formed by the electron transit layer 94B and the electron supply layer 94C. In another example, the buffer layer 94A may include the insulating layer 92. In this case, the buffer layer 94A may serve as an insulating layer that insulates the first semiconductor substrate 91 and the first and second transistors 51 and 52. In another example, the doped layer 94BA may be omitted from the nitride semiconductor layer 94. In another example, the buffer layer 94A may be omitted from the switch circuit chip 90. In these cases, the switch circuit chip 90 may include an insulating layer interposed between the first semiconductor substrate 91 and the electron transit layer 94B in the Z direction.
In each embodiment, the configuration of the switch circuit chip 90 (the first switch circuit chip 90A and the second switch circuit chip 90B) may be changed arbitrarily. In one example, source electrodes 97S may be provided for individual transistor elements. In this case, the source electrodes 97S may be electrically connected to one another by the source wiring 99S. In another example, the switch circuit chip 90 (the first switch circuit chip 90A and the second switch circuit chip 90B) may include, instead of the second pad 93B, a first source pad electrically connected to the source electrode 97S of the first transistor 51 and a second source pad electrically connected to the source electrode 97S of the second transistor 52. The first source pad may be connected to the fourth pad 83D of the control circuit chip 80 by a first source connector such as a wire. The second source pad may be connected to the fourth pad 83D of the control circuit chip 80 by a second source connector such as a wire. In this case, the ninth wire W9 may be omitted.
In the first embodiment, the configurations of the drive circuit chip 60 and the insulating chip 70 may be changed arbitrarily. In one example, the semiconductor device 10 may be configured such that the transformer 31 of the insulating chip 70 is built in the drive circuit chip 60. That is, the insulating chip 70 may be omitted. More specifically, as shown in FIG. 14, the fourth insulator 62 of the drive circuit chip 60 includes an insulating layer 62A provided over the fourth semiconductor layer 61A and a protective layer 62B provided over the insulating layer 62A. The transformer 31 is provided in the insulating layer 62A. The first coil 32 of the transformer 31 is electrically connected to the pulse signal generation circuit 21. The second coil 33 is electrically connected to the third pad 63C and the fourth pad 63D.
In the second embodiment, the position of the transformer 31 in a plan view may be changed arbitrarily. In one example, the transformer 31 may be disposed to overlap with at least one of the rectifier circuit 41 or the gate voltage control circuit 42 in a plan view.
In each embodiment, the configurations of the first insulating element and the second insulating element of the insulating chip 70 are not limited to the transformer 31, and may be changed arbitrarily. In one example, as shown in FIG. 15, the insulating chip 70 may include a capacitor 130 instead of the transformer 31. The capacitor 130 may include a first electrode plate 131 as the first insulating element and a second electrode plate 132 as the second insulating element. The first electrode plate 131 and the second electrode plate 132 are disposed to face each other in the Z direction. The first electrode plate 131 is disposed closer to the third semiconductor substrate 71 in the Z direction than the second electrode plate 132. The first electrode plate 131 is electrically connected to the first pad 73A by a first connection wiring 141. A configuration of the first connection wiring 141 may be the same as that of the first inner wiring 74 (see FIG. 4), for example. The second electrode plate 132 is electrically connected to the third pad 73C by a second connection wiring 142. A configuration of the second connection wiring 142 may be the same as that of the first outer wiring 75 (see FIG. 4), for example. In the first and second embodiments, the insulating chip 70 may omit the second pad 73B and the fourth pad 73D. Accordingly, the semiconductor device 10 may omit the fifth wire W5 and the seventh wire W7.
In each embodiment, the material constituting the fourth semiconductor substrate 61 of the drive circuit chip 60 may be changed arbitrarily. In one example, the fourth semiconductor substrate 61 may be formed by a nitride semiconductor. In addition, the drive circuit chip 60 may use a conductive substrate or an insulating substrate instead of the fourth semiconductor substrate 61.
In each embodiment, the material constituting the third semiconductor substrate 71 of the insulating chip 70 may be changed arbitrarily. In one example, the third semiconductor substrate 71 may be formed by a nitride semiconductor. In addition, the insulating chip 70 may use a conductive substrate or an insulating substrate instead of the third semiconductor substrate 71.
In each embodiment, the material constituting the second semiconductor substrate 81 of the control circuit chip 80 may be changed arbitrarily. In one example, the second semiconductor substrate 81 may be formed by a nitride semiconductor. In addition, the control circuit chip 80 may use a conductive substrate instead of the second semiconductor substrate 81.
In the first embodiment, the insulating chip 70 may be disposed at a position adjacent to the drive circuit chip 60 in the Y direction.
In the first embodiment, the insulating chip 70 may be mounted on the first die pad 101. In this case, the insulating chip 70 may be disposed at a position adjacent to the control circuit chip 80 in the Y direction.
In the first embodiment, the drive circuit chip 60 may be omitted from the semiconductor device 10. Accordingly, the first to third wires W1 to W3 may be omitted. In this case, the sixth terminal 114 may be omitted from the second support 110. Further, the fourth wire W4 connects the fourth terminal 112 and the first pad 63A of the drive circuit chip 60 to each other. The fifth wire W5 connects the fifth terminal 113 and the second pad 63B of the drive circuit chip 60 to each other.
In each embodiment, the second support 110, the drive circuit chip 60, and the insulating chip 70 may be omitted from the semiconductor device 10. That is, as shown in FIG. 16, the semiconductor device 10 may include the first die pad 101, the control circuit chip 80 and the switch circuit chip 90 mounted on the first die pad 101, and the sealing resin 120 that seals the first die pad 101, the control circuit chip 80, and the switch circuit chip 90. In this case, the semiconductor device 10 may include, as external terminals, the first to third terminals 102 to 104, the fourth terminal 105, and the fifth terminal 106. The first to third terminals 102 to 104 are the same as those in each embodiment. The fourth terminal 105 and the fifth terminal 106 are disposed on an opposite side of the first to third terminals 102 to 104 with respect to the first die pad 101. The fourth terminal 105 and the fifth terminal 106 are disposed to be spaced apart from the first die pad 101. The fourth terminal 105 and the fifth terminal 106 are partially sealed by the sealing resin 120.

The semiconductor device 10 includes a fourteenth wire W14 and a fifteenth wire W15. The fourteenth wire W14 and the fifteenth wire W15 are, for example, bonding wires, and are formed of a material including Au, Al, Cu, Ag, or the like. The fourteenth wire W14 and the fifteenth wire W15 are sealed by the sealing resin 120.

The fourteenth wire W14 connects the first pad 83A of the control circuit chip 80 and the fourth terminal 105 to each other. Thus, the first pad 83A and the fourth terminal 105 are electrically connected to each other. The fifteenth wire W15 connects the second pad 83B of the control circuit chip 80 and the fifth terminal 106 to each other. Thus, the second pad 83B and the fifth terminal 106 are electrically connected to each other. Therefore, the fourth terminal 105 and the fifth terminal 106 are electrically connected to the rectifier circuit 41 of the control circuit 40 (see FIG. 1).

In the modification shown in FIG. 16, the configuration of the control circuit chip 80 may be changed arbitrarily. In one example, like the control circuit chip 80 of the second embodiment, the control circuit chip 80 may include a transformer 31.
In each embodiment, the connectors for connecting the semiconductor chips to one another or connecting the semiconductor chips to the terminals are not limited to wires, and may be changed arbitrarily. For example, the connectors may be clips.

One or more of the various examples described in the present disclosure may be combined to the extent that they are not technically contradictory. The term “over” used in the present disclosure includes the meanings of “on” and “above” unless the context clearly indicates otherwise. Thus, for example, the expression “a first element is disposed over a second element” is intended to mean that in a certain embodiment, the first element may be disposed directly on the second element in contact with the second element, and in another embodiment, the first element may be disposed above the second element without being in contact with the second element. In other words, the term “over” does not exclude a structure in which another element is formed between the first element and the second element.

The term Z direction used in the present disclosure does not necessarily need to be the vertical direction, nor completely coincide with the vertical direction. Therefore, in various structures according to the present disclosure, “up” and “down” in the Z axis direction described in the present disclosure are not limited to “up” and “down” in the vertical direction. For example, the X direction may be the vertical direction or the Y direction may be the vertical direction.

### Supplementary Notes

Technical ideas that can be recognized from the present disclosure are set forth below. For the purpose of aiding understanding without any limiting purpose, components set forth in the supplementary notes are indicated by the reference numerals of the corresponding components in the above-described embodiments. The reference numerals are shown as examples to aid understanding, and the components set forth in each supplementary note should not be limited to the components indicated by the reference numerals.

### Supplementary Note 1

A Semiconductor Device (10), Including:
a first die pad (101);
a switch circuit chip (90) mounted on the first die pad (101);
a control circuit chip (80) mounted on the first die pad (101), and including a control circuit (40) configured to control driving the switch circuit chip (90);
a first conductive bonding material (SD1) configured to bond the first die pad (101) and the switch circuit chip (90);
a second conductive bonding material (SD2) configured to bond the first die pad (101) and the control circuit chip (80);
a first terminal (102) and a second terminal (103), which are disposed to be spaced apart from the first die pad (101); and
a sealing resin (120) configured to seal at least the first conductive bonding material (SD1), the second conductive bonding material (SD2), the switch circuit chip (90), and the control circuit chip (80), and configured to at least partially expose both the first terminal (102) and the second terminal (103),
wherein the switch circuit chip (90) includes:
   a first chip front surface (90S);
   a first chip rear surface (90R) opposite the first chip front surface (90S);
   a first semiconductor substrate (91) constituting the first chip rear surface (90R) and bonded to the first die pad (101) by the first conductive bonding material (SD1);
   an insulating layer (92) provided over the first semiconductor substrate (91); and
   a first transistor (51) and a second transistor (52), which are provided between the insulating layer (92) and the first chip front surface (90S) in a thickness direction of the switch circuit chip (90) (Z direction) and have sources connected to each other,
wherein both the first transistor (51) and the second transistor (52) are high electron mobility transistors including nitride semiconductors, and
wherein the source of the first transistor (51) and the source of the second transistor (52) are electrically connected to the first die pad (101) via the control circuit chip (80).

### Supplementary Note 2

The semiconductor device of Supplementary Note 1,
wherein the control circuit chip (80) includes:
   a second chip front surface (80S);
   a second chip rear surface (80R) opposite the second chip front surface (80S);
   a second semiconductor substrate (81) constituting the second chip rear surface (80R) and bonded to the first die pad (101) by the second conductive bonding material (SD2);
   a first output pad (83C) exposed from the second chip front surface (80S); and
   a second output pad (83D) electrically connected to the second semiconductor substrate (81) and exposed from the second chip front surface (80S),
wherein the switch circuit chip (90) includes:
   a first input pad (93A) exposed from the first chip front surface (90S) and electrically connected to both a gate of the first transistor (51) and a gate of the second transistor (52); and
   a second input pad (93B) exposed from the first chip front surface (90S) and electrically connected to the source of the first transistor (51) and the source of the second transistor (52), and
wherein the semiconductor device further includes:
   a first connector (W8) configured to connect the first output pad (83C) and the first input pad (93A) to each other; and
   a second connector (W9) configured to connect the second output pad (83D) and the second input pad (93B) to each other.

### Supplementary Note 3

The semiconductor device of Supplementary Note 1 or 2, further including a third terminal (104) integrated with the first die pad (101),
wherein a portion of the third terminal (104) is exposed from the sealing resin (120).

### Supplementary Note 4

The semiconductor device of Supplementary Note 3, wherein the third terminal (104) is disposed on a side where the first terminal (102) and the second terminal (103) are disposed with respect to the first die pad (101).

### Supplementary Note 5

The semiconductor device of Supplementary Note 4, wherein the third terminal (104) is provided between the first terminal (102) and the second terminal (103).

### Supplementary Note 6

The semiconductor device of any one of Supplementary Notes 1 to 5, wherein a thickness (T2) of the insulating layer (92) is smaller than a thickness (T1) of the first semiconductor substrate (91).

### Supplementary Note 7

The semiconductor device of any one of Supplementary Notes 1 to 6, wherein the insulating layer (92) is formed of a material containing AlN.

### Supplementary Note 8

The semiconductor device of Supplementary Note 7, wherein the switch circuit chip (90) includes a buffer layer (94A) provided over the insulating layer (92), and an electron transit layer (94B) provided over the buffer layer (94A),
wherein the buffer layer (94A) is formed of a material containing AlGaN,
wherein the electron transit layer (94B) includes a doped layer (94BA) formed of a material containing GaN doped with acceptor-type impurities, and
wherein the doped layer (94BA) is provided in the electron transit layer (94B) and disposed closer to the buffer layer (94A).

### Supplementary Note 9

The semiconductor device of Supplementary Note 8, wherein the switch circuit chip (90) includes:
an electron supply layer (94C) provided over the electron transit layer (94B) and formed by a nitride semiconductor having a larger band gap than the electron transit layer (94B);
a source electrode (97S) provided over the electron supply layer (94C);
a first drain electrode (97DA) and a second drain electrode (97DB), which are provided over the electron supply layer (94C) and disposed to be spaced apart from each other on both sides of the source electrode (97S); and
a gate electrode (97G) provided over the electron supply layer (94C) and disposed between the source electrode (97S) and the first drain electrode (97DA) and between the source electrode (97S) and the second drain electrode (97DB) in a plan view.

### Supplementary Note 10

The semiconductor device of Supplementary Note 9, wherein the switch circuit chip (90) includes a gate layer (96) interposed between the gate electrode (97G) and the electron supply layer (94C).

### Supplementary Note 11

The semiconductor device of any one of Supplementary Notes 1 to 10, further including:
a second die pad (111) disposed to be spaced apart from the first die pad (101);
an insulating chip (70) mounted on the second die pad (111); and
a relay connector (W6, W7) configured to electrically connect the insulating chip (70) and the control circuit chip (80) to each other,
wherein the sealing resin (120) seals the insulating chip (70) and the relay connector (W6, W7).

### Supplementary Note 12

The semiconductor device of Supplementary Note 11, further including:
a drive circuit chip (60) mounted on the second die pad (111); and
an intermediate connector (W4, W5) configured to connect the insulating chip (70) and the drive circuit chip (60) to each other,
wherein the sealing resin (120) seals the drive circuit chip (60) and the intermediate connector (W4, W5).

### Supplementary Note 13

The semiconductor device of Supplementary Note 12, wherein the insulating chip (70) is disposed between the drive circuit chip (60) and the control circuit chip (80) in an arrangement direction (X) of the first die pad (101) and the second die pad (102).

### Supplementary Note 14

The semiconductor device of any one of Supplementary Notes 11 to 13, wherein the insulating chip (70) includes:
a third chip front surface (70S);
a third chip rear surface (70R) opposite the third chip front surface (70S);
a third semiconductor substrate (71) constituting the third chip rear surface (70R);
a third insulator (72) provided over the third semiconductor substrate (71);
a first insulating element (32/131) provided in the third insulator (72); and
a second insulating element (33/132) provided in the third insulator (72) and disposed to face the first insulating element (32/131).

### Supplementary Note 15

The semiconductor device of any one of Supplementary Notes 1 to 10, further including:
a second die pad (111) disposed to be spaced apart from the first die pad (101);
a drive circuit chip (60) mounted on the second die pad (111); and
a chip connector (W12, W13) configured to connect the control circuit chip (80) and the drive circuit chip (60) to each other,
wherein the drive circuit chip (60) includes a drive circuit (20) configured to output a signal to the control circuit chip (80),
wherein the control circuit (40) includes a rectifier circuit (41) and a gate voltage control circuit (42) electrically connected to the rectifier circuit (41),
wherein the control circuit chip (80) includes a first insulating element (32/131) electrically connected to the drive circuit (20), and a second insulating element (33/132) disposed to face the first insulating element (32/131) and electrically connected to the rectifier circuit (41), and
wherein the sealing resin (120) seals the drive circuit chip (60) and the chip connector (W12, W13).

### Supplementary Note 16

The semiconductor device of any one of Supplementary Notes 1 to 10, further including:
a second die pad (111) disposed to be spaced apart from the first die pad (101);
a drive circuit chip (60) mounted on the second die pad (111); and
a chip connector (W12, W13) configured to connect the control circuit chip (80) and the drive circuit chip (60) to each other,
wherein the drive circuit chip (60) includes:
   a first insulating element (32/131);
   a second insulating element (33/132) disposed to face the first insulating element (32 or 131); and
   a drive circuit (20) configured to output a signal to the first insulating element (32/131),
wherein the control circuit chip (80) includes, as the control circuit (40), a gate voltage control circuit (42) and a rectifier circuit (41), and
wherein the sealing resin (120) seals the drive circuit chip (60) and the chip connector (W12, W13).

### Supplementary Note 17

The semiconductor device of Supplementary Note 12 or 13, further including:
a power supply terminal (112) and a signal terminal (114), which are disposed to be spaced apart from the second die pad (111);
a ground terminal (113) integrated with the second die pad (111);
a power supply connector (W1) configured to connect the drive circuit chip (60) and the power supply terminal (112) to each other; and
a signal connector (W3) configured to connect the drive circuit chip (60) and the signal terminal (114) to each other,
wherein the sealing resin (120) seals the power supply connector (W1) and the signal connector (W3), and partially seals the power supply terminal (112), the signal terminal (114), and the ground terminal (113).

### Supplementary Note 18

The semiconductor device of Supplementary Note 17, wherein the power supply terminal (112), the signal terminal (114), and the ground terminal (113) are disposed on an opposite side of the first die pad (101) with respect to the second die pad (111).

### Supplementary Note 19

The semiconductor device of any one of Supplementary Notes 1 to 18, wherein the switch circuit chip (90) includes a first power supply pad (93C) exposed from the first chip front surface (90S) and electrically connected to a drain of the first transistor (51), and a second power supply pad (93D) exposed from the first chip front surface (90S) and electrically connected to a drain of the second transistor (52),
wherein the semiconductor device further includes:
   a first power supply connector (W10) configured to connect the first power supply pad (93C) and the first terminal (102) to each other; and
   a second power supply connector (W11) configured to connect the second power supply pad (93D) and the second terminal (103) to each other, and
wherein the sealing resin (120) seals both the first power supply connector (W10) and the second power supply connector (W11).

### Supplementary Note 20

The semiconductor device of any one of Supplementary Notes 1 to 19, wherein the first semiconductor substrate (91) is formed of a material containing Si.

### Supplementary Note 21

The semiconductor device of Supplementary Note 2, wherein the second semiconductor substrate (81) is formed of a material containing Si.

### Supplementary Note 22

The semiconductor device of Supplementary Note 14, wherein the third semiconductor substrate (71) is formed of a material containing Si.

### Supplementary Note 23

The semiconductor device of any one of Supplementary Notes 14 to 16, wherein both the first insulating element and the second insulating element are a coil (32, 33).

### Supplementary Note 24

The semiconductor device of any one of Supplementary Notes 14 to 16, wherein both the first insulating element and the second insulating element are an electrode plate (131, 132).

### Supplementary Note 25

The semiconductor device of any one of Supplementary Notes 12, 13, and 15 to 18, wherein the drive circuit chip (60) includes a fourth chip front surface (60S), a fourth chip rear surface (60R) opposite the fourth chip front surface (60S), and a fourth semiconductor substrate (61) constituting the fourth chip rear surface (60R), and
wherein the fourth semiconductor substrate (61) is formed of a material containing Si.

### Supplementary Note 26

The semiconductor device of any one of Supplementary Notes 1 to 25, wherein the semiconductor device (10) further includes, as the switch circuit chips, a first switch circuit chip (90A) and a second switch circuit chip (90B),
wherein each of the first switch circuit chip (90A) and the second switch circuit chip (90B) includes a first transistor (51) and a second transistor (52) having sources connected in series to each other, and
wherein the source of the first transistor (51) and the source of the second transistor (52) of each of the first switch circuit chip (90A) and the second switch circuit chip (90B) are electrically connected to the first die pad (101) via the control circuit chip (80).

### Supplementary Note 27

The semiconductor device of Supplementary Note 26, wherein the control circuit chip (80) includes a first control circuit chip (80A) and a second control circuit chip (80B),
wherein each of the first control circuit chip (80A) and the second control circuit chip (80B) includes a second chip front surface (80S), a second chip rear surface (80R) opposite the second chip front surface (80S), and a second semiconductor substrate (81) constituting the second chip rear surface (80R) and bonded to the first die pad (101) by the second conductive bonding material (SD2),
wherein the first control circuit chip (80A) includes a first output pad (83CA) exposed from the second chip front surface (80S) of the first control circuit chip (80A), and a second output pad (83DA) electrically connected to the second semiconductor substrate (81) of the first control circuit chip (80A) and exposed from the second chip front surface (80S) of the first control circuit chip (80A),
wherein the second control circuit chip (80B) includes a third output pad (83CB) exposed from the second chip front surface (80S) of the second control circuit chip (80B), and a fourth output pad (83DB) electrically connected to the second semiconductor substrate (81) of the second control circuit chip (80B) and exposed from the second chip front surface (80S) of the second control circuit chip (80B),
wherein the first switch circuit chip (90A) includes a first input pad (93AA) exposed from the first chip front surface (90S) and electrically connected to both a gate of the first transistor (51) and a gate of the second transistor (52) of the first switch circuit chip (90A), and a second input pad (93BA) exposed from the first chip front surface (90S) and electrically connected to the source of the first transistor (51) and the source of the second transistor (52) of the first switch circuit chip (90A),
wherein the second switch circuit chip (90B) includes a third input pad (93AB) exposed from the first chip front surface (90S) and electrically connected to both a gate of the first transistor (51) and a gate of the second transistor (52) of the second switch circuit chip (90B), and a fourth input pad (93BB) exposed from the first chip front surface (90S) and electrically connected to the source of the first transistor (51) and the source of the second transistor (52) of the second switch circuit chip (90B), and
wherein the semiconductor device further includes:
   a first connector (W8A) configured to connect the first output pad (83CA) and the first input pad (93AA) to each other;
   a second connector (W9A) configured to connect the second output pad (83DA) and the second input pad (93BA) to each other;
   a third connector (W8B) configured to connect the third output pad (83CB) and the third input pad (93AB) to each other; and
   a fourth connector (W9B) configured to connect the fourth output pad (83DB) and the fourth input pad (93BB) to each other;

### Supplementary Note 28

The semiconductor device of Supplementary Note 27, wherein the control circuit (40) includes a first control circuit (40A) and a second control circuit (40B),
wherein the first control circuit chip (80A) includes the first control circuit (40A),
wherein the second control circuit chip (80B) includes the second control circuit (40B),
wherein the first control circuit (40A) includes a first rectifier circuit (41A) and a first gate voltage control circuit (42A), which are electrically connected to the first switch circuit chip (90A), and
wherein the second control circuit (40B) includes a second rectifier circuit (41B) and a second gate voltage control circuit (42B), which are electrically connected to the second switch circuit chip (90B).

### Supplementary Note 29

An insulating switch (800), including:
the semiconductor device (10) of any one of Supplementary Notes 1 to 28;
a power supply circuit (821) electrically connected to the semiconductor device (10) and configured to supply an operating voltage to the semiconductor device (10); and
a signal generation circuit (822) electrically connected to the semiconductor device (10) and configured to output a control signal (S1) for controlling a load (810) electrically connected to the semiconductor device (10).

The above descriptions are merely exemplary. Those skilled in the art may recognize that many more possible combinations and replacements can be adopted other than the components and methods (manufacturing processes) listed for the purpose of describing the technique of the present disclosure. The present disclosure is intended to embrace all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a first die pad;
a switch circuit chip mounted on the first die pad;
a control circuit chip mounted on the first die pad, and including a control circuit configured to control driving the switch circuit chip;
a first conductive bonding material configured to bond the first die pad and the switch circuit chip;
a second conductive bonding material configured to bond the first die pad and the control circuit chip;
a first terminal and a second terminal, which are disposed to be spaced apart from the first die pad; and
a sealing resin configured to seal at least the first conductive bonding material, the second conductive bonding material, the switch circuit chip, and the control circuit chip, and configured to at least partially expose both the first terminal and the second terminal,
wherein the switch circuit chip comprises:
a first chip front surface;
a first chip rear surface opposite the first chip front surface;
a first semiconductor substrate constituting the first chip rear surface, and bonded to the first die pad by the first conductive bonding material;
an insulating layer provided over the first semiconductor substrate; and
a first transistor and a second transistor, which are provided between the insulating layer and the first chip front surface in a thickness direction of the switch circuit chip and have sources connected to each other,
wherein both the first transistor and the second transistor are high electron mobility transistors including nitride semiconductors, and
wherein the source of the first transistor and the source of the second transistor are electrically connected to the first die pad via the control circuit chip.

2. The semiconductor device of claim 1,
wherein the control circuit chip comprises:
a second chip front surface;
a second chip rear surface opposite the second chip front surface;
a second semiconductor substrate constituting the second chip rear surface, and bonded to the first die pad by the second conductive bonding material;
a first output pad exposed from the second chip front surface; and
a second output pad electrically connected to the second semiconductor substrate and exposed from the second chip front surface,
wherein the switch circuit chip further comprises:
a first input pad exposed from the first chip front surface and electrically connected to both a gate of the first transistor and a gate of the second transistor; and
a second input pad exposed from the first chip front surface and electrically connected to the source of the first transistor and the source of the second transistor, and
wherein the semiconductor device further comprises:
a first connector configured to connect the first output pad and the first input pad to each other; and
a second connector configured to connect the second output pad and the second input pad to each other.

3. The semiconductor device of claim 1, further comprising a third terminal integrated with the first die pad,
wherein a portion of the third terminal is exposed from the sealing resin.

4. The semiconductor device of claim 3, wherein the third terminal is disposed on a side where the first terminal and the second terminal are disposed with respect to the first die pad.

5. The semiconductor device of claim 4, wherein the third terminal is provided between the first terminal and the second terminal.

6. The semiconductor device of claim 1, wherein a thickness of the insulating layer is smaller than a thickness of the first semiconductor substrate.

7. The semiconductor device of claim 1, wherein the insulating layer is formed of a material containing AlN.

8. The semiconductor device of claim 7, wherein the switch circuit chip further comprises a buffer layer provided over the insulating layer, and an electron transit layer provided over the buffer layer,
wherein the buffer layer is formed of a material containing AlGaN,
wherein the electron transit layer includes a doped layer formed of a material containing GaN doped with acceptor-type impurities, and
wherein the doped layer is provided in the electron transit layer and disposed closer to the buffer layer.

9. The semiconductor device of claim 8, wherein the switch circuit chip further comprises:
an electron supply layer provided over the electron transit layer and formed by a nitride semiconductor having a larger band gap than the electron transit layer;
a source electrode provided over the electron supply layer;
a first drain electrode and a second drain electrode, which are provided over the electron supply layer and disposed to be spaced apart from each other on both sides of the source electrode; and
a gate electrode provided over the electron supply layer and disposed between the source electrode and the first drain electrode and between the source electrode and the second drain electrode in a plan view.

10. The semiconductor device of claim 9, wherein the switch circuit chip further comprises a gate layer interposed between the gate electrode and the electron supply layer.

11. The semiconductor device of claim 1, further comprising:
a second die pad disposed to be spaced apart from the first die pad;
an insulating chip mounted on the second die pad; and
a relay connector configured to electrically connect the insulating chip and the control circuit chip to each other,
wherein the sealing resin seals the insulating chip and the relay connector.

12. The semiconductor device of claim 11, further comprising:
a drive circuit chip mounted on the second die pad; and
an intermediate connector configured to connect the insulating chip and the drive circuit chip to each other,
wherein the sealing resin seals the drive circuit chip and the intermediate connector.

13. The semiconductor device of claim 12, wherein the insulating chip is disposed between the drive circuit chip and the control circuit chip in an arrangement direction of the first die pad and the second die pad.

14. The semiconductor device of claim 11, wherein the insulating chip comprises:
a third chip front surface;
a third chip rear surface opposite the third chip front surface;
a third semiconductor substrate constituting the third chip rear surface;
a third insulator provided over the third semiconductor substrate;
a first insulating element provided in the third insulator; and
a second insulating element provided in the third insulator and disposed to face the first insulating element.

15. The semiconductor device of claim 1, further comprising:
a second die pad disposed to be spaced apart from the first die pad;
a drive circuit chip mounted on the second die pad; and
a chip connector configured to connect the control circuit chip and the drive circuit chip to each other,
wherein the drive circuit chip comprises a drive circuit configured to output a signal to the control circuit chip,
wherein the control circuit comprises a rectifier circuit and a gate voltage control circuit electrically connected to the rectifier circuit,
wherein the control circuit chip further comprises a first insulating element electrically connected to the drive circuit, and a second insulating element disposed to face the first insulating element and electrically connected to the rectifier circuit, and
wherein the sealing resin seals the drive circuit chip and the chip connector.

16. The semiconductor device of claim 1, further comprising:
a second die pad disposed to be spaced apart from the first die pad;
a drive circuit chip mounted on the second die pad; and
a chip connector configured to connect the control circuit chip and the drive circuit chip to each other,
wherein the drive circuit chip includes a first insulating element, a second insulating element disposed to face the first insulating element, and a drive circuit configured to output a signal to the first insulating element,
wherein the control circuit chip further comprises, as the control circuit, a gate voltage control circuit and a rectifier circuit, and
wherein the sealing resin seals the drive circuit chip and the chip connector.

17. The semiconductor device of claim 12, further comprising:
a power supply terminal and a signal terminal, which are disposed to be spaced apart from the second die pad;
a ground terminal integrated with the second die pad;
a power supply connector configured to connect the drive circuit chip and the power supply terminal to each other; and
a signal connector configured to connect the drive circuit chip and the signal terminal to each other,
wherein the sealing resin seals the power supply connector and the signal connector, and partially seals the power supply terminal, the signal terminal, and the ground terminal.

18. The semiconductor device of claim 17, wherein the power supply terminal, the signal terminal, and the ground terminal are disposed on an opposite side of the first die pad with respect to the second die pad.

19. The semiconductor device of claim 1,
wherein the switch circuit chip further comprises:
a first power supply pad exposed from the first chip front surface and electrically connected to a drain of the first transistor; and
a second power supply pad exposed from the first chip front surface and electrically connected to a drain of the second transistor,
wherein the semiconductor device further comprises:
a first power supply connector configured to connect the first power supply pad and the first terminal to each other; and
a second power supply connector configured to connect the second power supply pad and the second terminal to each other, and
wherein the sealing resin seals both the first power supply connector and the second power supply connector.

20. An insulating switch, comprising:
the semiconductor device of claim 1;
a power supply circuit electrically connected to the semiconductor device and configured to supply an operating voltage to the semiconductor device; and
a signal generation circuit electrically connected to the semiconductor device and configured to output a control signal for controlling a load electrically connected to the semiconductor device.
